(19) United States
(12) Patent Application Publication
(10) Pub. No.: US 2024/0094636 A1
(43) Pub. Date: Mar. 21, 2024

(54) Methods for Making Probe Arrays Utilizing Deformed Templates

(71) Applicant: Microfabrica Inc., Van Nuys, CA (US)

(72) Inventor: Onnik Yaglioglu, Chatsworth, CA (US)

(73) Assignee: Microfabrica Inc., Van Nuys, CA (US)

(21) Appl. No.: 17/390,835

(22) Filed: Jul. 30, 2021

Related U.S. Application Data
(60) Provisional application No. 63/059,131, filed on Jul. 30, 2020.

(51) Int. Cl. G03F 7/09; G01R 1/073

(52) U.S. Cl. CPC G03F 7/09; G01R 1/07307; G03F 7/094

(57) ABSTRACT

Probe array formation embodiments of the invention (e.g., that are used to form full arrays or multi-probe subarrays that are to be assembled into full arrays) provide simultaneous formation of many probes of an array or subarray while the probes are in an array configuration. These embodiments provide for the creation and deformation of array formation templates that include holes or openings for depositing probe material wherein the openings are either fully formed (i.e. fully actualized) prior to deformation or are latently formed by chemical or structural changes to the template material

### RELATED APPLICATIONS

The below table sets forth the priority claims for the instant application along with filing dates, patent numbers, and issue dates as appropriate. Each of the listed applications is incorporated herein by reference as if set forth in full herein including any appendices attached thereto.

| | Continuity | | Which | Which | Which | Dkt No. |
|---|---|---|---|---|---|---|
| App. No. | Type | App. No. | was Filed | is now | issued on | Fragment |
| This | claims | 63/059,131 | 2020 Jul. 30 | pending | — | 393-A |
| application | benefit of | | | | | |

### FIELD OF THE INVENTION

The present invention relates generally to the field of probe arrays or subarrays for testing (e.g. wafer level testing or socket testing) of electronic components (e.g. integrated circuits), more particularly to the formation of such arrays or subarrays using at least one deposition template that has been deformed from a first array configuration containing latent openings, actualized openings, or deposited probe material occupying at least portions of such openings to a second array configuration containing latent openings, actualized openings, or deposited probe material occupying at least portions of such openings, wherein the second array configuration is different from the first array configuration by at least one of a change in orientation of the openings or deposited probe material at least partially filling the openings, or a change in shape of the openings or deposited probe material.

### BACKGROUND OF THE INVENTION

### Probes

Numerous electrical contact probe and pin configurations as well as array formation methods have been commercially used or proposed, some of which may be prior art while others are not. Examples of such pins, probes, arrays, and methods of making are set forth in the following patent applications, publications of applications, and patents. Each of these applications, publications, and patents is incorporated herein by reference as if set forth in full herein as are any teachings set forth in each of their prior priority applications.

| U.S. Pat App No., Filing Date | |
|---|---|
| U.S. App Pub No., Pub Date | |
| U.S. Patent No., Pub Date | First Named Inventor, “Title” |
| 10/772,943 - Feb. 4, 2004 | Arat, et al., “Electrochemically Fabricated Microprobes” |
| 2005-0104609 - May 19, 2005 | |
| — | |
| 10/949,738 - Sep. 24, 2004 | Kruglick, et al., “Electrochemically Fabricated Microprobes” |
| 2006-0006888 - Jan. 12, 2006 | |
| — | |
| 11/028,945 - Jan. 3, 2005 | Cohen, et al., “A Fabrication Process for Co-Fabricating a |
| 2005-0223543 - Oct. 13, 2005 | Multilayer Probe Array and a Space Transformer |
| 7,640,651 - Jan. 5, 2010 | |
| 11/028,960 - Jan 3, 2005 | Chen, et al. “Cantilever Microprobes for Contacting |
| 2005-0179458 - Aug. 18, 2005 | Electronic Components and Methods for Making Such |
| 7,265,565 - Sep. 4, 2007 | Probes |
| 11/029,180 - Jan. 3, 2005 | Chen, et al. “Pin-Type Probes for Contacting Electronic |
| 2005-0184748 - Aug. 25, 2005 | Circuits and Methods for Making Such Probes” |
| — | |
| 11/029,217 - Jan. 3, 2005 | Kim, et al., “Microprobe Tips and Methods for Making” |
| 2005-0221644 - Oct. 6, 2005 | |
| 7,412,767 - Aug. 19, 2008 | |
| 11/173,241 - Jun. 30, 2005 | Kumar, et al., Probe Arrays and Method for Making |
| 2006-0108678 - May 25, 2006 | |
| — | |
| 11/178,145 - Jul. 7, 2005 | Kim, et al., “Microprobe Tips and Methods for Making” |
| 2006-0112550 - Jun. 1, 2006 | |
| 7,273,812 - Sep. 25, 2007 | |
| 11/325,404 - Jan. 3, 2006 | Chen, et al., “Electrochemically Fabricated Microprobes” |
| 2006-0238209 - Oct. 26, 2006 | |
| — | |
| 14/986,500 - Dec. 31, 2015 | Wu, et al. “Multi-Layer, Multi-Material Micro-Scale and |
| 2016-0231356 - Aug. 11, 2016 | Millimeter-Scale Devices with Enhanced Electrical and/or |
| 10,215,775 - Feb. 26, 2019 | Mechanical Properties” |
| 16/172,354 - Oct. 18, 2018 | Chen, et al. “Pin-Type Probes for Contacting Electronic |
| 2019-0204354 - Jul. 4, 2019 | Circuits and Methods for Making Such Probes” |
| — | |
| 16/584,818 - Sep. 26, 2019 | Smalley, “Probes Having Improved Mechanical and/or |
| — | Electrical Properties for Making Contact between Electronic |
| — | Circuit Elements and Methods for Making” |
| 16/584,863 - Sep. 26, 2019 | Frodis, “Probes Having Improved Mechanical and/or |
| — | Electrical Properties for Making Contact between Electronic |
| — | Circuit Elements and Methods for Making” |
| 62/961,672 - Jan. 15, 2020 | Wu, “Compliant Pin Probes with Multiple Spring Segments |
| (P-US381-B-MF) | and Compression Spring Deflection Stabilization |
| | Structures, Methods for Making, and Methods for Using” |
| 62/961,675 - Jan. 15, 2020 | Wu, “Probes with Multiple Springs, Methods for Making, |
| (P-US382-B-MF) | and Methods for Using” |
| 62/961,678 - Jan. 15, 2020 | Wu, “Compliant Pin Probes with Flat Extension Springs, |
| (P-US383-B-MF) | Methods for Making, and Methods for Using” |
| 16/791,288 - Feb. 14, 2020 | Frodis, “Multi-Beam Vertical Probes with Independent Arms |
| (P-US385-A-MF) | Formed of a High Conductivity Metal for Enhancing Current |
| | Carrying Capacity and Methods for Making Such Probes” |
| 62/985,859 - Mar. 5, 2020 | Veeramani, “Probes with Planar Unbiased Spring Elements |
| (P-US379-B-MF) | for Electronic Component Contact and Methods for Making |
| | Such Probes” |
| 63/015,450 - Apr. 24, 2020 | Lockard, “Buckling Beam Probe Arrays and Methods for |
| (P-US390-A-MF) | Making Such Arrays Including Forming Probes with Lateral |
| | Positions Matching Guide Plate Hole Positions and |
| | Integrating Guides” |
| 63/055,892 - Jul. 23, 2020 | Yaglioglu, “Improved Methods for Making Probe Arrays |
| (P-US392-A-MF) | Utilizing Plastic Deformation” |
| 63/064,888 - Aug. 12, 2020 | Lockard, “Probe Arrays and Improved Methods for Making |
| (P-US388-A-MF) | and Using Spring Preforms That Undergo Longitudinal |
| | Deformation and/or Stretching While in Array Formation” |
| 17/139,925 - Dec. 31, 2020 | NP OF 379-B |
| (P-US398-A-MF) | Veeramani, “Probes with Planar Unbiased Spring Elements |
| | for Electronic Component Contact and Methods for Making |
| | Such Probes” |
| 17/139,933 - Dec. 31, 2020 | NP OF 381-B |
| (P-US399-A-MF) | Wu, “Compliant Pin Probes with Multiple Spring Segments |
| | and Compression Spring Deflection Stabilization |
| | Structures, Methods for Making, and Methods for Using” |
| 17/139,936 - Dec. 31, 2020 | NP OF 382-B |
| (P-US400-A-MF) | Wu, “Probes with Multiple Springs, Methods for Making, |
| | and Methods for Using” |
| 17/139,940 - Dec. 31, 2020 | NP OF 383-B |
| (P-US401-A-MF) | Wu, “Compliant Pin Probes with Flat Extension Springs, |
| | Methods for Making, and Methods for Using” |
| 17/240,962 - Apr. 26, 2021 | NP OF 390-A |
| (P-US405-A-MF) | Lockard, “Buckling Beam Probe Arrays and Methods for |
| | Making Such Arrays Including Forming Probes with Lateral |
| | Positions Matching Guide Plate Hole Positions” |
| 63/217,721 - Jul. 1, 2021 | Wu, “Compliant Pin Probes with Extension Springs, |
| (P-US402-B-MF) | Methods for Making, and Methods for Using” |
| 17/320,173 - May 13, 2021 | NP OF 378-A |
| (P-US406-A-MF) | Lockard, “Vertical Probe Arrays and Improved Methods for |
| | Making Using Temporary or Permanent Alignment |
| | Structures for Setting or Maintaining Probe-to-Probe |
| | Relationships” |
| 17/384,680 - Jul. 23, 2021 | NP OF 392-A |
| (P-US407-A-MF) | Yaglioglu, “Improved Methods for Making Probe Arrays |
| | Utilizing Lateral Plastic Deformation of Probe Preforms” |

### SUMMARY OF THE INVENTION

It is a first object of some embodiments of the invention to provide an improved method of forming a probe array that has a plurality of angled probes (i.e., the direction defined by lines running through the top and bottom end of the probes do not extend perpendicular to a plane of the top or bottom of the array).
It is a second object of some embodiments of the invention to provide an improved method of forming a probe array that has probes with first and second ends that point in non-parallel directions with respect to each other.
It is a third object of some embodiments of the invention to provide an improved method of forming a probe array that has probes that include curved portions.
It is a fourth object of some embodiments of the invention to provide an improved method of forming a probe array that has a plurality of individual probes with multiple differently oriented linear or curved segments.
It is a fifth object of some embodiments of the invention to provide an improved method of forming a probe array that has a plurality of individual probes with longitudinally extending segments (straight or curved) that point in at least partially opposing lateral directions.
It is a sixth object of some embodiments of the invention to provide an improved method of forming a probe array that includes a plurality of probes along with a dielectric compliant material (e.g., a plastically and/or elastically deformable material) between at least portions of some probes.
It is a seventh object of some embodiments of the invention to provide an improved method of forming a probe array using at least one deposition template having openings (i.e. a material formed or patterned to have openings for receiving a deposited material and for holding the deposited material in a desired configuration at least temporarily) that comprises at least one deformable material wherein the template material has latent openings (i.e. patterned but not yet emptied) that are expressive of probes in one or more particular orientations, wherein the deposition template material is deformed to reshape or reorient the latent openings to create deformed patterns in preparation for depositing one or more probe materials, and then expressing the latent deformed patterns to form openings for receiving the at least one probe material and holding it at least temporarily in a desired configuration.
It is an eighth object of some embodiments of the invention to provide an improved method of forming a probe array using at least one deposition template that comprises at least one deformable material wherein the template has openings that are expressive of probes in one or more particular orientations, wherein the deposition template is deformed to reshape or reorient the openings to create deformed openings for receiving one or more probe materials.
It is a ninth object of some embodiments of the invention to provide an improved method of forming a probe array using at least one deposition template that comprises at least one deformable material wherein a plurality of openings have received probe material that is expressive of probes in one or more particular orientations or shapes, whereafter the template containing the probe material is deformed to reshape or reorient the probe material to create a probe array having deformed probes.
It is a tenth object of some embodiments of the invention to provide an improved method of forming a probe array using at least one deposition template comprising at least one deformable material for simultaneously forming a plurality of probes in an array configuration wherein the template material is provided with latent openings (i.e., patterned but not yet emptied, e.g., in the form of a selectively exposed photoresist that has not yet undergone development) or existing openings that are expressive of probes in one or more particular orientations or having one or more particular configurations that are plastically deformed to provide one or more different orientations or one or more different configurations prior to depositing one or more probe materials into the openings after deformation and full expression.
It is an eleventh object of some embodiments of the invention to provide an improved method of forming a probe array using at least one deposition template comprising at least one deformable material for simultaneously forming a plurality of probes in an array configuration, wherein the template material is provided with latent openings (i.e., patterned but not yet emptied, e.g., in the form of a selectively exposed photoresist that has not yet undergone development) or existing openings that are expressive of probes in one or more particular orientations or in having one or more particular configurations that are elastically deformed to provide one or more different orientations or one or more different configurations prior to depositing one or more probe materials into the openings while held in a deformed state and after full expression of the openings.
It is a twelfth object of some embodiments of the invention to provide an improved method of forming a probe array using at least one deposition template comprising at least one deformable material for simultaneously forming a plurality of probes in an array configuration wherein the template material is provided with latent openings (i.e., patterned but not yet emptied, e.g., in the form of a selectively exposed photoresist that has not yet undergone development) or existing openings that are expressive of probes in one or more particular orientations or in having one or more particular configurations that are both elastically and plastically deformed to provide one or more different orientations or one or more different configurations prior to depositing one or more probe materials into the openings after while held in the deformed state and after full expression of the openings.
It is a thirteenth object of some embodiments of the invention to provide an improved method of forming a probe array using at least one deposition template comprising at least one deformable material for simultaneously forming a plurality of probes in an array configuration wherein the template prior to receiving deposition of one or more probe materials is deformed using, at least in part, gravity to provide a shearing force between two longitudinal levels of the template (e.g. between a top of the template and a bottom of the template or between a middle longitudinal portion of the template and the top and/or bottom of the template).
It is a fourteenth object of some embodiments of the invention to provide an improved method of forming a probe array using at least one deposition template comprising at least one deformable material for simultaneously forming a plurality of probes in an array configuration wherein the template prior to receiving deposition of one or more probe materials is deformed using, at least in part, a shearing force that is applied between at least two longitudinal levels (e.g. between a top of the template and a bottom of the template, between a middle longitudinal portion of the template and the top and/or bottom of the template, or between two intermediate portions of the template), by lateral and relative movement of two or more relatively rigid deformation structures that occupy at least portions of the lateral extents of the template that are located at the at least two longitudinal levels.
It is a fifteenth object of some embodiments of the invention to provide an improved method of forming a probe array using at least one deposition template comprising at least one deformable material for simultaneously forming a plurality of probes in an array configuration wherein the template prior to receiving one or more deposited probe materials is deformed using, at least in part, a shearing force that is applied between at least two longitudinal levels (e.g. between a top of the template and a bottom of the template, between a middle longitudinal portion of the template and the top and/or bottom of the template, or between two intermediate longitudinal portions of the template), by lateral and relative movement of two or more relatively rigid deformation structures that occupy at least portions of the lateral extents of the template that are located at the at least two longitudinal levels and wherein the shearing force is removed prior to depositing at least one probe material into openings in the deformed template.
It is a sixteenth object of some embodiments of the invention to provide an improved method of forming a probe array similar to that of the fifteenth object with the exception that the shearing force, or at least the deformation tools, holding the template in a deformed state are not removed prior to depositing the at least one probe material in into openings.
It is a seventeenth object of some embodiments of the invention to provide an improved method of forming a probe array using at least one deposition template comprising at least one deformable material for simultaneously forming a plurality of probes in an array configuration wherein the template prior to use is deformed using, at least in part, a shearing force that is applied between at least two longitudinal levels (e.g. between a top of the template and a bottom of the template, between a middle longitudinal portion of the template and the top and/or bottom of the template, or between two intermediate portions of the template), by lateral and relative movement of two or more relatively rigid deformation structures that occupy at least portions of the lateral extents of the template that are located at the at least two longitudinal levels and wherein at least one of the two or more deformation structures are removed prior to depositing at least one probe material into the openings in the deformed template.
It is an eighteenth object of some embodiments of the invention to provide an improved method of forming a probe array similar to that of the seventeenth object the deformation structures, as necessary, continue to hold the template in a deformed state while depositing the at least one probe material into the deformed openings.
It is a nineteenth object of some embodiments of the invention to provide an improved method of forming a probe array using at least one deposition template comprising at least one deformable material for simultaneously forming a plurality of probes in an array configuration wherein the template prior to depositing at least one probe material into openings in the template, undergoes deformation, at least in part, by relative lateral movement of a shearing or deformation tool (e.g. a plate) that is bonded to a longitudinal level of the template.
It is an twentieth object of some embodiments of the invention to provide an improved method of forming a probe array using at least one deposition template comprising at least one deformable material for simultaneously forming a plurality of probes in an array configuration wherein the template prior to depositing at least one of one or more probe materials, is deformed using, at least in part, at least one shearing or deformation tool (e.g., the substrate or a plate longitudinally displaced from the substrate) that has protruding elements that can extend relatively short distances (e.g. <20% of the template height, <10% of the template height, <5% of the template height, <2% of the template height, or <1% of the template height) into probe material deposition holes in the template to engage the template for lateral shearing (i.e. for lateral displacement).
It is a twenty-first object of some embodiments of the invention to provide an improved method of forming a probe array that uses at least one deposition template comprising at least one deformable material for simultaneously forming a plurality of probes in an array configuration wherein the template prior to depositing at one of one or more probe materials, is deformed using, at least in part, at least one shearing or deformation tool (e.g., the substrate or a plate longitudinally displaced from the substrate) that has protruding elements that can extend relatively short distances (e.g. <20% of the template height, <10% of the template height, <5% of the template height, <2% of the template height, or <1% of the template height) into non-probe-material-deposition holes in the template to engage the template for lateral shearing (i.e. for lateral displacement).
It is a twenty-second object of some embodiments of the invention to provide an improved method of forming a probe array using at least one deposition template comprising at least one deformable material for simultaneously forming a plurality of probes in an array configuration wherein the template prior to depositing at least one of one or more probe materials, is deformed using, at least in part, at least one shearing or deformation tool (e.g., the substrate or a plate longitudinally displaced from the substrate) that has protruding elements that can extend relatively short distances (e.g. <20% of the template height, <10% of the template height, <5% of the template height, <2% of the template height, or <1% of the template height) into the template away from (e.g. laterally displaced from) probe material deposition holes in the template wherein the protruding elements are encapsulated by, and bonded to, template material so as to engage the template material to aid in lateral shearing (i.e. for lateral displacement).
It is a twentieth-third object of some embodiments of the invention to provide an improved method of forming a probe array that uses at least one deposition template comprising at least one deformable material for simultaneously forming a plurality of probes in an array configuration wherein the template prior to depositing at one of one or more probe materials, is deformed using, at least in part, at least one shearing or deformation structure (e.g. a relative rigid mesh structure, a structure with embedded anchoring elements) that can be directly or indirectly pushed and/or pulled laterally to cause displacement of at least one longitudinal portion of the template relative to a different longitudinal portion of the template.
It is a twenty-fourth object of some embodiments of the invention to provide an improved method of forming a probe array that uses a deformed template for simultaneously forming a plurality of probes in an array configuration wherein the template is formed via deposition of a single layer of a photoresist or photopolymer, followed by lithographic exposure to form a plurality of latent deposition holes for receiving at least one probe material, development of the latent holes to express the associated openings, wherein development of the template material occurs after the exposure but before or after deformation that changes the shape and/or orientation of the plurality of openings to produce the deformed template, and wherein deposition of probe material into the openings occurs after development and may occur either before or after deformation.
It is a twenty-fifth object of some embodiments of the invention to provide an improved method of forming a probe array that uses a deformed template for simultaneously forming a plurality of probes in an array configuration wherein the template is formed via deposition of a plurality of layers of a photoresist or photopolymer, followed by lithographic exposure to form latent deposition holes in all layers for receiving at least one probe material, then development of the latent patterns to express associated openings, wherein development of the template material occurs after the exposure but before or after deformation that changes the shape and/or orientation of the plurality of openings to produce the deformed template, and wherein deposition of probe material into the openings occurs after development and may occur either before or after deformation.
It is a twenty-sixth object of some embodiments of the invention to provide an improved method of forming a probe array that uses a deformed deposition template for simultaneously forming a plurality of probes in an array configuration wherein the template is formed via deposition of a plurality of layers of a photoresist or photopolymer, wherein patterning to produce the deformable template occurs via L deposited layers of M materials, E exposure operations, and D development operations, and deformation that changes the shape and/or orientation of the plurality of holes to produce the deformed template, where L>=E >=D, where L>1, and where L>=M>=1.
It is a twenty-seventh object of some embodiments of the invention to provide an improved method of forming a probe array that uses a deformed template for simultaneously forming a plurality of probes in an array configuration wherein the template is formed via deposition or location of at least one layer of a template material and patterning of at least one template material to produce a plurality of holes via laser machining and then deformation that changes the shape and/or orientation of the plurality of holes to produce the deformed template, wherein the patterning of the at least one template material may occur before or after.
It is a twenty-eighth object of some embodiments of the invention to provide a multi-use deformation tool for use in an improved method of forming a probe array using a template with a plurality of deposition holes into which probe material will be deposited after use of the multi-use deformation tool to deform the template and either before or after removal of the deformation tool.

It is an object of some embodiments of the invention to reduce the time and/or effort of producing probe arrays (e.g. buckling beam probe arrays).

It is an object of some embodiments of the invention to reduce the cost of production of forming probe arrays or probe heads (e.g. buckling beam probe arrays or probe heads).

It is an object of some embodiments of the invention to provide an improved method of forming probe arrays that decouple a cost for forming an array from the number of probes in the array.

It is an object of some embodiments of the invention to provide an improved method of forming probe arrays that at least partially decouple a cost for forming the array from the number of probes in the array by eliminating or reducing labor cost associated with assembling of individual probes into the array configuration, by allowing for assembly of probe arrays from groups of probes where individual groups each include a plurality of probes that are formed together in an array configuration.

It is another object of some embodiments of the invention to provide an improved method of forming probe arrays that at least partially decouple a lead time for forming the array from the number of probes in the array.

It is another object of some embodiments of the invention to provide an improved method of forming probe arrays that decouple a lead time for forming probes and probe arrays from such probes from the number of probes in the array by eliminating or reducing time associated with assembling of individual probes into the array configuration, by allowing for assembly of probe arrays or probe preform arrays from groups of probes where individual groups each include a plurality of probes or probe preforms that are formed together in an array configuration.

It is another object of some embodiments of the invention to provide an improved method of forming probe arrays that for a reduction in assembly errors associated with creating probe arrays by reducing the number of assembly steps involved in creating the probe arrays by decoupling the number of assembly operations from the number of probes in the array or at least reducing the number of assembly operation to small fraction of the number of probes in the array (e.g. where the number of assembly steps is less than the number of probes by a factor of 10, 20, 50, 100, 200, 500, or even 1000, or more).

It is another object of some embodiments of the invention to provide probes with configurations that are angled or curved, have multiple angles or curves relative to a longitudinal axis of a probe array with reduced numbers of stair-steps associated with probes formed from a plurality of stacked layers or even complete elimination of such stair steps.

Additional objects of the invention provide more reliable, faster, less labor intensive, and/or lower cost formation of probe arrays. Still other objects of some embodiments of the invention might provide improved probe arrays or tools for making such probe arrays. Still other objects of some embodiments of the invention might provide uses of the methods set forth herein to form three-dimensional structures other than probe arrays or probes such as medical devices, RF or microwave devices (e.g. antennas, waveguides, or filters), sensors, scanning mirrors, other spring or compliant devices, or the like.

Other objects and advantages of various embodiments of the invention will be apparent to those of skill in the art upon review of the teachings herein. The various embodiments of the invention, set forth explicitly herein or otherwise ascertained from the teachings herein, may address one or more of the above objects alone or in combination, or alternatively may address some other object ascertained from the teachings herein. It is not intended that all objects, or even multiple objects, be addressed by any single aspect or embodiment of the invention even though that may be the case regarding some aspects.

In a first aspect of the invention, a method for forming a probe array, includes: (a) providing a substrate; (b) locating at least one deformable template material directly or indirectly on the substrate or on a previously located template material, wherein the at least one template material has a bottom and a top and extends in a longitudinal direction from the bottom to the top with the bottom located closer to the substrate than the top; (c) patterning the at least one deformable template material to form a plurality of openings that extend in the longitudinal direction; (d) exerting a lateral shearing displacement by application of a lateral shearing force between at least two longitudinal levels of at least one of the at least one template material to deform the at least one of the at least one template material to create a deformed template that results in at least a portion of the plurality of openings being deformed to become deformed openings having orientation changes relative to the openings prior to deformation; and (e) depositing at least one probe material into the deformed openings in the deformed template to form probes for the probe array.

Numerous variations of the first aspect of the invention are possible and include, for example: (1) the deformed template being, at least in part, plastically deformed, (2) the deformed template being initially provided with a larger deformation that is reduced, at least in part, upon removal of the lateral displacement that applied the shearing due to the presence of at least a portion of the deformation being caused by elastic deformation; (3) the probe array being put to use with at least a portion of the at least one template material remaining in place; (4) the portion of the template material that remains in place, providing an elastic response to deformation during use of the probe array, (5) substantially all of the at least one template material is removed from the array before putting the probe array to use; (6) the deformation of the template resulting in each of a plurality of probes having at least one straight but angled segment; (7) the deformation of the template resulting in each of a plurality of probes having at least two straight but angled segments; (8) the deformation of the template resulting in each of a plurality of probes having at least two straight but angled segments that are directed in at least partially opposing lateral directions; (9) the deformation of the template resulting in each of a plurality of probes having at least two straight but angled segments that lie in at least two different planes that each include an array normal (i.e., a normal direction perpendicular to a nominal plane defined by the ends of at least a portion of the probes forming the array); (10) the deformation of the template resulting in each of a plurality of probes having at least one curved segment; (11) the deformation of the template resulting in each of a plurality of probes having at least curved segments located in a position selected from the group consisting of (i) serially with respect to one another along the length of the probe and (ii) in parallel with one another; (12) the substrate including a space transformer; (13) the substrate being a build substrate that is removed with another substrate being bonded to one end of the plurality of probes; (14) providing at least one deformation tool that is used in deforming the template material wherein the at least one deformation tool includes a plurality of openings which are laterally aligned with the plurality of probes and wherein the at least one deformation tool is located at at least one longitudinal position to engage the probes at at least one longitudinal height and wherein at least one of the at least one deformation tool is retained as at least one guide plate in the array when put to use; (15) the at least one deformable material is selected from the group consisting of: (i) a single template material (e.g. a photoresist) that is subjected to differential processing (e.g. temperature and timing of baking, type of radiation used for exposure and quantity of exposure, and type of developer used and parameters associated with its use) at at least two longitudinal levels such that the template material has different yield strengths which in turn results in different amounts of relative deformation at that two levels when the at least one template material is subjected to the lateral displacement, and (ii) at least two different template materials (e.g. two different photoresists having different base materials, different reactive chemicals, different viscosities, different coefficients of radiation absorption, or the like) which have at least two different yield strengths which in turn results in different amounts of relative deformation at the at least two levels when the at least two different template materials are subjected to the lateral displacement; (16) the at least two different portions of the at least one deformable material undergoing differential processing prior to locating each of the at least two different portions such that the at least two different portions will have different yield strengths at the time of exerting the lateral shearing displacement; and (17) combinations of two or more of variations (1)-(16). Other variations are also possible and may be based on the objects of the invention set forth above or variations of the embodiments set forth hereafter.

In a second aspect of the invention, a method for forming a probe array, includes: (a) providing a substrate; (b) locating at least one deformable template material directly or indirectly on the substrate or on a previously located template material, wherein the at least one template material has a bottom and a top and extends in a longitudinal direction from the bottom to the top with the bottom located closer to the substrate than the top; (c) patterning the at least one deformable template material to form a plurality of latent openings that extend in the longitudinal direction; (d) exerting a lateral shearing displacement by application of a lateral shearing force between at least two longitudinal levels of at least one of the at least one template material to deform the at least one of the at least one template material to create a deformed latent template that results in at least a portion of the plurality of latent openings being deformed to become deformed latent openings having orientation changes relative to latent openings prior to deformation; (e) removing material from the latent openings to provide actualized openings; and (f) after providing the actualized openings, depositing at least one probe material into the deformed actualized openings in the deformed template to form probes for the probe array.

Numerous variations of the second aspect of the invention are possible and include for example those variations noted above for the first aspect of the invention, mutatis mutandis. Other variations are also possible and may be based on the objects of the invention set forth above or variations of the embodiments, set forth hereafter.

In a third aspect of the invention, a method for forming a probe array having a plurality of probes, includes: (a) providing a substrate; (b) locating at least one deformable template material directly or indirectly on the substrate or on a previously located template material, wherein the at least one template material has a bottom and a top and extends in a longitudinal direction from the bottom to the top with the bottom located closer to the substrate than the top; (c) patterning the at least one deformable template material to form a plurality of openings that extend in the longitudinal direction, selected from the group consisting of (1) latent openings and (2) actualized openings; (d) exerting a lateral shearing displacement by application of a lateral shearing force between at least two longitudinal levels of at least one of the at least one template material to deform the at least one of the at least one template material to create a deformed template with openings that result in at least a portion of the plurality of openings being deformed such that orientation changes occur relative to orientation of the openings prior to deformation; (e) actualizing any latent opening by removing material from the latent openings to provide actualized openings; and (f) after providing actualized openings, depositing at least one probe material into the actualized openings to form a plurality of probes for the probe array.

Numerous variations of the second aspect of the invention are possible and include, for example variations to the order of processing such as: (1) patterning followed by exerting, followed by actualizing, and then followed by depositing, (2) patterning followed by actualizing, followed by exerting, and then followed by depositing, (3) patterning followed by actualizing, followed by depositing, and then followed by exerting, (4) patterning and actualizing occurring simultaneously, followed by exerting, and then depositing, and (5) patterning and actualizing occurring simultaneously, followed by depositing, and then by exerting. Other variations may include, for example those variations noted above for the first aspect of the invention, mutatis mutandis. Still other variations are also possible and may be based on the objects of the invention set forth above or variations of the embodiments, set forth hereafter.

In a fourth aspect of the invention, a method for forming a microscale or millimeter scale structure or arrays of structures, includes: (a) providing a substrate; (b) locating at least one deformable template material directly or indirectly on the substrate or on a previously located template material, wherein the at least one template material has a bottom and a top and extends in a longitudinal direction from the bottom to the top with the bottom located closer to the substrate than the top; (c) patterning the at least one deformable template material to form a plurality of openings that extend in the longitudinal direction, selected from the group consisting of (1) latent openings and (2) actualized openings; (d) exerting a lateral shearing displacement by application of a lateral shearing force between at least two longitudinal levels of at least one of the at least one template material to deform the at least one of the at least one template material to create a deformed template with openings that result in at least a portion of the plurality of openings being deformed such that orientation changes occur relative to orientation of the openings prior to deformation; (e) actualizing any latent opening by removing material from the latent openings to provide actualized openings; and (f) after providing actualized openings, depositing at least one structural material into the actualized openings to form a plurality of structures.

In a fifth aspect of the invention, a method for forming a probe array having a plurality of probes, includes: (a) providing a substrate; (b) locating at least one deformable template material directly or indirectly on the substrate or on a previously located template material, wherein the at least one template material has a bottom and a top and extends in a longitudinal direction from the bottom to the top with the bottom located closer to the substrate than the top; (c) patterning the at least one deformable template material to form a plurality of openings that extend in the longitudinal direction, selected from the group consisting of (1) latent openings and (2) actualized openings; (d) exerting a lateral shearing displacement by application of a lateral shearing force between at least two longitudinal levels of at least one of the at least one template material to deform the at least one of the at least one template material to create a deformed template with openings that result in at least a portion of the plurality of openings being deformed such that orientation changes occur relative to orientation of the openings prior to deformation; (e) actualizing any latent opening by removing material from the latent openings to provide actualized openings; and (f) after providing actualized openings, depositing at least one probe material into the actualized openings to form a plurality of probes for the probe array, wherein the process includes one or more features selected from the group consisting of: (i) the at least one deformable material includes a plurality of deposits of the same material, (ii) the at least one deformable material includes a plurality of placements of films of the same material, (iii) the at least one deformable material includes a plurality of deposits of different materials with at least some having different deformation compliances, (iv) the at least one deformable material includes a plurality of placements of films of different materials with at least some having different deformation compliances, (v) the exerting of a lateral shearing displacement occurs from a single pair of longitudinally displaced displacement tools, (vi) a displacement tool includes at least one element on one side of the template material that provide a continuous and longitudinally extended contact surface with the template material (which may be planar or curved) such that the shape of the contact surface transfers to the template material when laterally driven into the template material and thus imparts a desired shape of the template material, (vii) a displacement tool with at least two elements with at least one on each side of the template material provides a continuous and longitudinally extended contact surface with the template material (which may be planar or curved) such that the shape of the contact surface translates to a shape of deformation at any given longitudinal level, and wherein the shapes of the tools on either side are complementary so that when one side provides a compressive deformation force at the given longitudinal level the other side does not but the other side may provide such a compressive force at a different longitudinal level such that openings in the template take on a back and forth oscillating configuration, or at least a configuration with at least a single change in tilting direction; (viii) the exerting occurs with at least three and perhaps four or more longitudinally displacement tools; (ix) the exerting occurs using at least one deformation tool that includes longitudinally extending tabs or pins that engage the template material to push the material at a plurality of laterally displaced positions during deformation; and (x) the exerting occurs using at least one deformation tool that includes longitudinally extending tabs or pins that engage the template material to pull the material at a plurality of laterally displaced positions during deformation.

In other aspects of the invention, methods of forming probe arrays using template deformation techniques (e.g. using deformation tools) include functional combinations or subcombinations of steps, functionalities, or features along with functional orders for using those steps, functionalities, or features found or ascertainable from the generalized embodiments, alternative implementations of those generalized embodiments, the specific embodiments, or alternative implementations or variations of those specific embodiments.

In other aspects of the invention, methods of forming a probe array using template deformation techniques include the steps, functionality, and/or features noted in the above objects of the invention as (1) individually set forth, (2) set forth in separate alternatives noted with regard to some objectives, or (3) set forth in a combination of such objectives or separate alternatives for those objectives, so long as the combination does not completely remove all the benefits offered by each of the separate objectives or alternatives.

In other aspects, deformation tools and their use includes the functionality or features noted in the above objects of the invention as (1) individually set forth, (2) set forth in separate alternatives noted with regard to some objectives, or (3) set forth in a combination of such objectives or separate alternatives for those objectives, so long as the combination does not completely remove all the benefits offered by each of the separate objectives or alternatives.

In still other aspects, deformation tools and their use include the combinations of features, steps, or functionalities as set forth herein along with subcombinations of the such features, steps, or functionalities as set forth in the specific embodiments, or alternative implementations of those specific embodiments in any functional manner to achieve one of the objectives noted herein (e.g. as directly set forth or set forth by incorporation), or as otherwise ascertainable from the teachings herein.

Other aspects of the invention will be understood by those of skill in the art upon review of the teachings herein and, for example, may include alternatives in the configurations or processes set forth herein, decision branches noted in those processes or configurations, or partial or complete exclusion of such alternatives and/or decision branches in favor of explicitly setting forth process steps or features along with orders to be used in performing such steps or connections between such features. Some aspects may provide devices (e.g. probe arrays or probes) that result from or are counterparts to the method of formation aspects. Other aspects may provide for methods of use for the probe arrays provided herein. Other aspect may provide devices that are not probes or probe arrays but which are produced by the methods set forth therein wherein such devices may have microscale or millimeter scale dimensions.

### BRIEF DESCRIPTION OF THE DRAWINGS

FIGS. 1A-1F schematically depict the formation of a first layer of a structure using adhered mask plating where the blanket deposition of a second material overlays both the openings between deposition locations of a first material and the first material itself.

FIG. 1G depicts the completion of formation of the first layer resulting from planarizing the deposited materials to a desired level.

FIGS. 1H and 1I respectively depict the state of the process after formation of the multiple layers of the structure and after release of the structure from the sacrificial material.

FIG. 2 provides a generalized flowchart for fabricating probe arrays that includes the location or deposition of at least one template material directly or indirectly on a substrate with the template material patterned with openings for receiving deposition of probe material, deformation of the template material after latent or actualized patterning of the template material, and deposition of at least one probe material into actualized openings either before or after deformation (e.g. by electrochemical deposition).

FIGS. 3A-3E illustrate various states of a process for forming a probe array according to a first array formation embodiment that uses a single layer template material that is deformed with little resulting boundary effect which is followed by subsequent deposition of a single probe material, which is followed by removal of the template material to leave a completed or partially completed probe array adhered to the substrate.

FIGS. 4A-4E illustrate various states of a process for forming a probe array according to a second array formation embodiment where some boundary effect from template deformation occurs near the interface of the template material and the substrate.

FIGS. 5A-5E illustrate various states of a process for forming a probe array according to a third embodiment where some boundary effects at both the bottom and top of the template material result from template deformation.

FIGS. 6A-6E illustrate various states of a process for forming a probe array according to a fourth array formation embodiment where probe material is deposited into opening in the template material prior to deformation of the template material.

FIGS. 7A-7F illustrate various states of a process for forming a probe array according to a fifth array formation embodiment wherein prior to deformation the template material undergoes exposure to form latent patterns in the template material that are developed or otherwise removed after deformation.

FIGS. 8A-8E illustrate various states of a process for forming a probe array according to a sixth array formation embodiment where probes are formed from two materials that are deposited into the openings of a deformed template.

FIGS. 9A-9E illustrate various states of a process for forming a probe array according to a seventh array formation embodiment wherein probes are formed from two different materials like the embodiment of FIGS. 8A-8E but where a portion of the template material is retained as part of the array structure.

FIGS. 10A-10F illustrate various states of a process for forming a probe array according to an eighth array formation embodiment of the invention that is similar to the embodiment of FIGS. 9A-9E but where all of the template material is removed and a different material is thereafter made to surround the lower portions of the probes as part of the array structure.

FIGS. 11A-11E illustrate various states of a process for forming a probe array according to a ninth array formation embodiment wherein two levels of different stacked template materials are used such that upon template deformation the lower material, which has a lower yield strength (e.g., higher compliance or lower spring constant) than the upper material, undergoes more deformation than the upper material such that a probe array with not only tilted probes is created but an array with curved or bent probes is formed.

FIGS. 12A-12E illustrate various states of a process for forming a probe array according to a tenth array formation embodiment of the invention that is similar to the embodiment of FIGS. 11A-11E but with the stacking of the higher yield strength and lower yield strength materials reversed such that upon template deformation the upper portion of the template tends to undergo more deformation and the lower portion.

FIGS. 13A-13E illustrate various states of a process for forming a probe array according to an eleventh array formation embodiment of the invention wherein three stacked template materials are used with the middle material having a lower yield strength (e.g., higher compliance or lower spring constant) than the lower and upper materials such that upon template deformation the middle material tends to undergo more deformation than does the top and bottom materials.

FIGS. 14A1-14H4 provide schematic illustrations of template deformation methods and tools according to eight different deformation methods and/or tooling embodiments wherein undeformed templates are shown along with anticipated results of deformation.

FIGS. 15A-15F illustrate various states of a process for forming a probe array according to a twelfth array formation embodiment of the invention wherein patterning of template material occurs through openings in at least one deformation tool wherein the openings in the deformation tool may alternatively be made before or after locating the deformation tool above the template material.

FIGS. 16A-16F2 illustrate various states of a process for forming a probe array according to a thirteenth array formation embodiment of the invention wherein two levels of template material are used along with two deformation tools in addition to the substrate, which acts as a third deformation tool, wherein two alternative deformation examples are provided, one with a tilted, bent probes and the other with a C-shaped or chevron shaped probes.

FIGS. 17A-17D illustrate another deformation tool and formation example wherein the tool is embedded into template material at a desired longitudinal level such that deposited probe material never contacts the deformation tool.

### DETAILED DESCRIPTION OF PREFERRED EMBODIMENTS

### Electrochemical Fabrication in General

Various implementations of the present invention may use single or multi-layer electrochemical deposition processes that are similar to those set forth in U.S. Pat. No. 6,027,630, issued on Feb. 22, 2000 to Adam Cohen or in U.S. Pat. No. 5,190,637 to Henry Guckel,

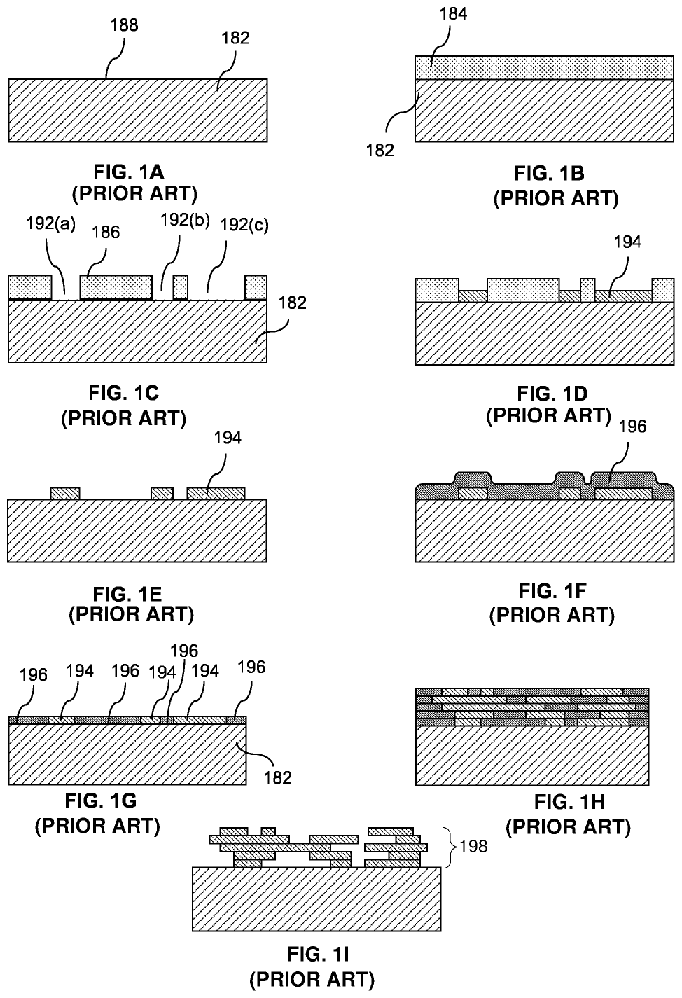

FIGS. 1A-1I are provided to illustrate techniques that may be useful. FIGS. 1A-1I illustrate side views of various states in an example multi-layer, multi-material electrochemical fabrication process. FIGS. 1A-1G illustrate various stages in the formation of a single layer of a multi-layer fabrication process where a second metal is deposited on a first metal as well as in openings in the first metal so that the first and second metals form part of the layer. In FIG. 1A, a side view of a substrate 182 having a surface 188 is shown, onto which patternable photoresist 184 is deposited, spread, or cast as shown in FIG. 1B. In FIG. 1C, a pattern of resist is shown that results from the curing, exposing, and developing of the resist. The patterning of the photoresist 184 results in openings or apertures 192(a)-192(c) extending from a surface 186 of the photoresist through the thickness of the photoresist to surface 188 of the substrate 182. In FIG. 1D, a metal 194 (e.g. nickel) is shown as having been electroplated into the openings 192(a)-192(c). In FIG. 1E, the photoresist has been removed (i.e. chemically stripped) from the substrate to expose regions of the substrate 182 which are not covered with the first metal 194. In FIG. 1F, a second metal 196 (e.g. silver) is shown as having been blanket electroplated over the entire exposed portions of the substrate 182 (which is conductive) and over the first metal 194 (which is also conductive). FIG. 1G depicts the completed first layer of the structure which has resulted from the planarization of the first and second metals down to a height that exposes the first metal and sets a thickness for the first layer. In FIG. 1H, the result of repeating the process steps shown in FIGS. 1B-1G several times to form a multi-layer structure is shown where each layer consists of two materials. For most applications, one of these materials is removed as shown in FIG. 1I to yield a desired 3-D structure 198 (e.g. component or device).

Though the primary focus of the present application is formation of structures and particularly array structures using template formation and forced deformation, the deposition processes and multilayer processes in '630 and '337 patents are advantageously utilized.

### Some Definitions

Definitions of various terms and concepts that may be used in understanding the embodiments of the invention (either for the devices themselves, certain methods for making the devices, or certain methods for using the devices) will be understood by those of skill in the art. Some such terms and concepts are discussed herein while other such terms are addressed in the various patent applications to which the present application claims priority and/or which are incorporated herein by reference.

The term “longitudinal” as used herein refers to a long dimension of a probe, an end-to-end dimension of the probe, or a tip-to-tip dimension. Longitudinal may refer to a generally straight line that extends from one end of the probe to another end of the probe or it may refer to a curved or stair-stepped path that has a sloped or even changing direction along a height of the probe. When referring to probe arrays, the longitudinal dimension may refer to a particular direction the probes in the array point or extend, but it may also simply refer to the overall height of the array that starts at a plane containing a first end, tip, or base of a plurality of probes and extends perpendicular thereto to a plane containing a second end, tip, or top of the probes. The context of use typically makes clear what is meant especially to those of skill in the art. It is intended that the interpretation to be applied to the term herein be as narrow as warranted by the details of the description provided or the context in which the term is used. If however, no such narrow interpretation is warranted, it is intended that the broadest reasonable scope of interpretation apply.

The term “lateral” as used herein is related to the term longitudinal. In terms of the stacking of layers, lateral refers to a direction within each layer, or two perpendicular directions within each layer (i.e. one or more directions that lie within a plane of a layer that is substantially perpendicular to the longitudinal direction). When referring to probe arrays, laterally generally has a similar meaning in that a lateral dimension is generally a dimension that lies in a plane that is parallel to a plane of the top or bottom of the array (i.e. substantially perpendicular to the longitudinal dimension). When referring to probes themselves, the lateral dimensions may be those that are perpendicular to an overall longitudinal axis of the probe, a local longitudinal axis of the probe (that is local lateral dimensions), or simply the dimensions similar to those noted for arrays or layers. The context of use typically makes clear what is meant especially to those of skill in the art. It is intended that the interpretation to be applied to the term herein be as narrow as warranted by the details of the description provided or the context in which the term is used. If no such narrow interpretation is warranted, it is intended that the broadest reasonable scope of interpretation apply.

### Generalized Probe Array and Probe Array Formation Embodiments

Probe arrays, methods of making probe arrays, tools for making probe arrays, and methods of using probe arrays can take on different forms in different embodiments of the invention. Probe array formation embodiments of the invention provide simultaneous formation of many probes of an array or of a subarray while those probes are laterally positioned relative to one another in an array configuration and possibly while those probes are provided with shapes corresponding to final non-biased configurations or at least configurations that are non-linear and/or do not have longitudinal probe axes that are parallel to a longitudinal axis of the array or subarray. These embodiments provide for the creation and deformation of array formation templates (e.g. electroplating templates) that include holes or openings for depositing probe material wherein the openings are either fully formed (i.e. fully actualized) prior to deformation or are latently formed by chemical or structural changes to the template material prior to deformation with development to remove selected regions of the template material occurring after deformation. Though deposition of probe material into the openings in a template material generally occurs after deformation (such that during deformation, the openings are expressing a final probe orientation or probe shape), in some embodiments deposition of probe material may occur prior to any deformation or may occur after only partial deformation has occurred. In some embodiments, the deformation of a template, prior to probe material deposition, may result in probes being built up (e.g., probe material being deposited) in what is largely a final unbiased shape or configuration (exclusive of internal deposition stresses, work hardening stresses, and the like, which may result from formation of the probes in the template, or tempering or stress relieving operations that the probes may be subjected to during subsequent processing) while in other embodiments, the shaping of the template may provide the probes with a configuration that is not a final configuration but a starting configuration that may be further manipulated, e.g., by the methods of the '680 application previously incorporated herein by reference, or by the methods of one or more of the other applications incorporated herein by reference. In some embodiments, deformation of a template after probe material deposition, may or may not result in probes being formed with a final unbiased shape as in some embodiments, further plastic deformation of the probes individually or in one or more groups may occur after releasing the probes from the deposition template. As used herein, final unbiased probe configuration may refer to a real configuration that a probe or group of probes takes on or it may refer to a hypothetical unbiased configuration that would exist if all biasing forces were to be removed which in practice may not actually occur as partially shaped probes may undergo further plastic deformation where biasing forces associated with such deformation may never be fully removed as the probes may be retained by guide plates, or other structures, in a biased state wherein part of the probe shape is from shape as formed plus plastic deformation (i.e. unbiased shape) while the remaining portion of the probe shape is from biased retained elastic deformation. In some embodiments, at the time of template deformation, the template may have a thickness that is equal to or greater than a longitudinal height of the probe array while in other embodiments, the thickness of the template may be less than the array height such that multiple levels of template material may be deposited and shaped to achieve full array height.

Different embodiments of the invention may make use of different deformation tools to cause or allow optimized control of deformation. Such tools may take on different configurations such as, for example: (1) thin plate-like structures without holes; (2) thin plate-like structures with holes corresponding to probe openings, (3) thin plate like structures with holes that are used for one or more purposes other than deposition of probe material; (4) structures that will contact deposited probe material upon deposition of probe material; (5) structures that will not contact deposited probe material, though still present during probe material deposition, (6) structures that are at least partially embedded at one or more longitudinal levels within the template material, (7) structures at one or more longitudinal levels above, below, or within a body of template material that may be pushed, pulled, or tilted during deformation, (8) mesh-like structures that provide adequate rigidity to aid in deformation, (9) structures that are bonded at desired longitudinal levels or in lateral positions relative to one or more template materials, and (10) structures that have tabs that engage at least some holes within a template material to cause lateral movement of the template material upon lateral and/or longitudinal movement of the structure, and the like.

In some embodiments, template material may include, for example: (1) one or more negative photoresists with sufficient conformability at the time of deformation to allow desired change in shape, (2) one or more positive photoresists with sufficient conformability at the time of deformation to allow desired change in shape, (3) a solidified or gelled photopolymer with sufficient conformability at the time of deformation to allow desired change in shape, (4) a laser patternable material with sufficient conformability at the time of deformation to allow desired change in shape, (5) a deformable material (either compressible or not) that undergoes plastic deformation when subjected to deformation whereby a deformation tool may be removed after deformation either before or after deposition of probe material, (6) a deformable material (either compressible or not) that undergoes elastic deformation when subjected to deformation whereby a deformation tool remains in place after deformation at least until after deposition of probe material occurs or deposition of a different shape retention material in non-probe openings occurs, (7) a deformable material (either compressible or not) that undergoes deformation and then has its material properties changed to set its shape in the deformed configuration.

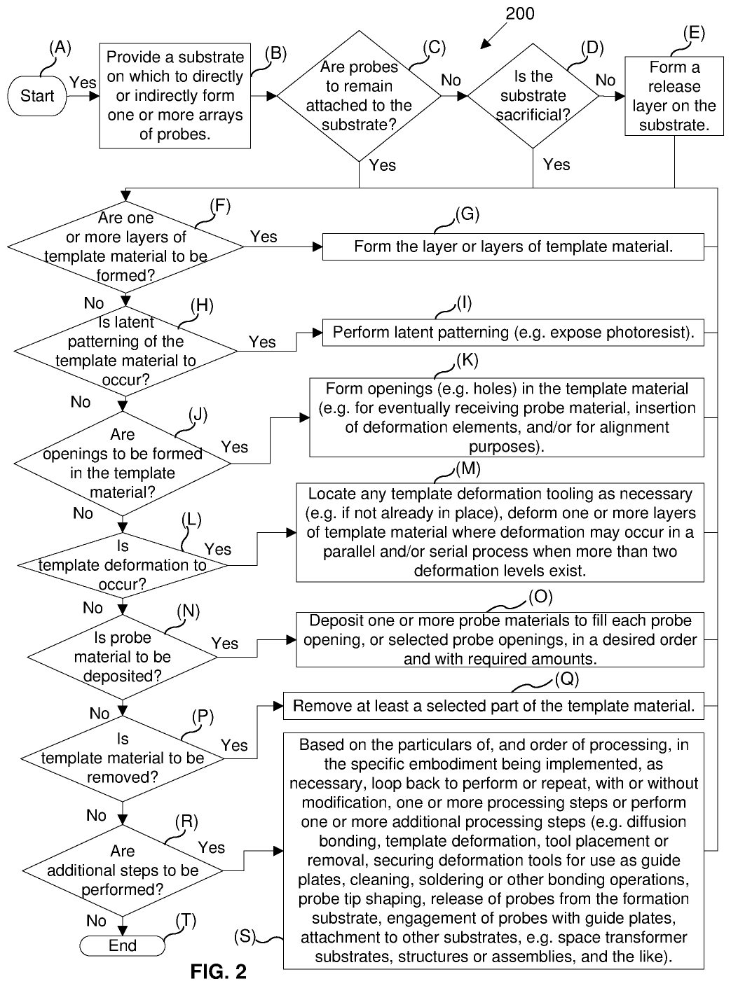

FIG. 2 provides a generalized flowchart for fabricating a probe array using at least one deposition template material that is deformed to provide transformation of probe configurations or orientations after patterning of the template material with actualized or latent openings for receiving probe material. The deformation of the template material may occur using one or more deformation tools (one of which may include a relatively rigid substrate on which the probes are directly or indirectly attached). The flowchart 200 of FIG. 2 includes blocks (A)-(T) with blocks (C), (D), (F), (H), (J), (L), (N), (P), and (R) representing inquiries or decision blocks, blocks (B), (E), (G), (I), (K), (M), (O), (Q) and (S) representing process steps or groups of steps that may be performed, while (A) and (T) represent process initiation and termination blocks. It is not intended that the process of FIG. 2 represent a single process with all the indicated steps and inquires being made one after another in the order indicated or even being performed, but instead it is intended to provide a framework which may be used in defining numerous alternative processes. Some such alternatives may include most of the process steps and/or decision operations while others may include a much smaller subset of the process steps along with only some or even none of the decision operations. In actual implementations, process operations, decisions, and/or processing order may be manually implemented, implemented under machine control, programmed computer or microprocessor control, or be implemented by a combination of one or more of these. Depending on the order in which process steps are to be executed, a first loop through blocks (F)-(S) may result in one or more steps being performed while one or more subsequent loops may repeat those steps, perform one or more other steps, or result in the performance of a combination of the two. During implementation, numerous process steps and decisions not explicitly noted in the flowchart may be performed including, for example, cleaning steps, activation steps, material annealing or tempering steps, inspection or testing steps, decisions based on the outcome of one or prior steps, removal and rework steps, and the like. In some embodiments, some steps may be split into sub-steps, other steps may be implemented between the sub-steps that have been split from one another, and/or only a portion of those sub-steps actually performed. Each embodiment will include performance of operations (G), (K), (M), and (O) at least once but not necessarily in this order as in some embodiments (O) may performed prior to (M).

The general process flow of FIG. 2 may be executed using different combinations of steps, different orders of steps, different repetitions of steps, and using different alternative implementations of steps or groups of steps that will be apparent to one of skill in the art upon review of the teachings herein (including the teachings incorporated herein by reference).

### Specific Embodiment Examples

To further enhance understanding of the scope of the generalized formation embodiment discussed above, specific illustrative examples are set forth below. These examples use reference numbers wherein the first digit(s) are based on the FIG. number while the final two digits, and possibly an extension, indicate specific features of the embodiments as exemplified in the following table.

| Ref. No. (Final Two | |
|---|---|
| Digits - Extension) | Description |
| 00 | Flowchart |
| 01 | Substrate |
| 11 | Single layer template material, or template material |
| 11-1 | Lower layer template material, or template material (first layer) |
| 11-2 | Middle layer template material, or template material (second layer) |
| 11-3 | Upper layer template material |
| 21 | Openings for receiving a probe material |
| 23-1 | Latent openings having been formed (i.e. locations that will eventually |
| | become openings for receiving a probe material |
| 23-2 | Openings formed (corresponding to latent openings) |
| 31 | Lateral shearing (relative movement to cause deformation) |
| 33 | Gravity induced deformation (direction of force of gravity) |
| 34-1 | Interface edge |
| 34-2 | Interface bend |
| 35 | Upward force applied to substrate by supporting structure |
| 37 | Relative movement to cause deformation |
| 39 | Relative lateral displacement (applied at same time) |
| 39-1, -2 | Relative lateral displacement |
| 41 | Single probe material |
| 43 | First probe material |
| 45 | Second probe material |
| 47 | Tip material |
| 51 | Region of removed template material |
| 61, -1, -2 | Completed or partially completed probe array |
| 63 | Array of probes partially embedded in template material |
| 65 | Partially embedded array in different material |
| 71 | Different material to partially embed probes |
| 81 | Side arms or plates |
| 91 | Deformation plate |
| 91-1 | Deformation plate (without openings) |
| 91-2 | Deformation plate (with openings) |
| 93 | Engagement tabs |
| 93-1 | Engagement tabs (substrate) |
| 93-2 | Engagement tabs (probe material openings) |
| 93-3 | Engagement tabs (non-probe openings) |
| 95 | Deformation tool |
| 95-1 | Deformation tool (intermediate) |
| 95-2 | Deformation tool (upper) |
| 96-1, -2 | Deformation tool handle |

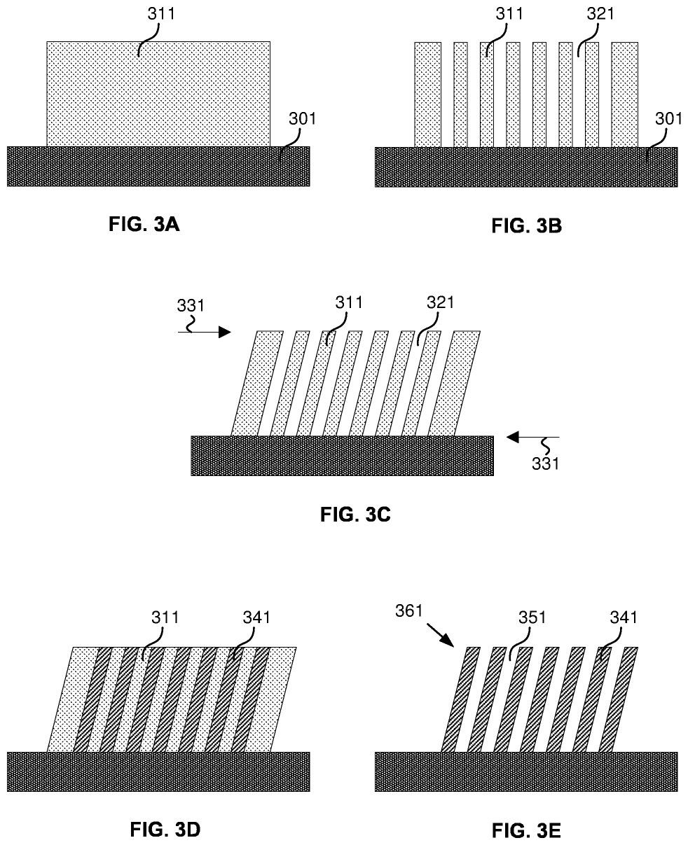

FIGS. 3A-3E illustrate various states of a process for forming a probe array according to a first array formation embodiment of the invention. FIG. 3A illustrates the state of the fabrication process after a single layer of template material 311 is deposited or located over a substrate 301. FIG. 3B illustrates the state of the process after openings 321 for receiving a probe material are created in the template material wherein the openings are intended to receive material for forming a plurality of probes of a single array or for multiple arrays. For example, a photoresist material may receive selectively applied radiation that either cross-links the exposed areas or that breaks down the photoresist in the exposed areas such that exposed regions or unexposed regions can be developed to remove selected material. In another example, the voids may be created by exposure to ablative radiation that directly removes the template material from selected locations. The probe array or arrays may be linear or two-dimensional arrays, and the arrays may or may not have uniform spacings from probe-to-probe. FIG. 3C illustrates the state of the process after the patterned template is deformed by lateral shearing 331 with little boundary effect due to the specific process and parameters used and/or due to the compliant and/or elastic nature of the template material. FIG. 3D illustrates the state of the process after a single probe material 341 is deposited into the deformed openings of the template material wherein the deposit may also be planarized to more accurately control the height of the resulting probe material. Such planarization may also remove some of the template material. FIG. 3E illustrates the state of the process after the remaining template material is removed 351 leaving a completed or partially completed probe array 361 adhered to the substrate.

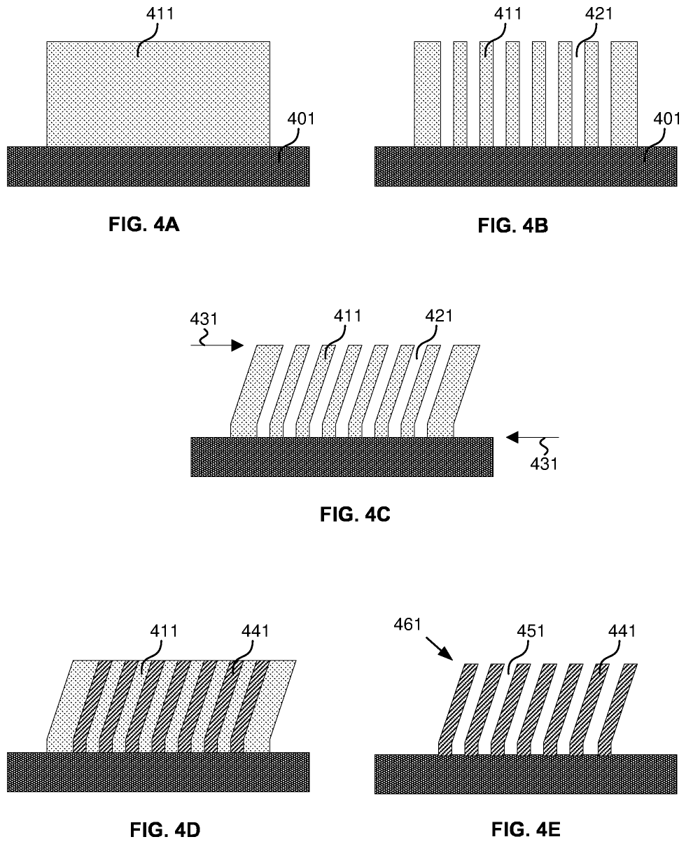

FIGS. 4A-4E illustrate various states of a process for forming a probe array according to a second array formation embodiment of the invention. FIG. 4A illustrates the state of the process after a single layer of template material 411 is deposited or located over a substrate 401. FIG. 4B illustrates the state of the process after openings 421 for receiving a probe material are created. FIG. 4C illustrates the state of the process after the template is deformed by lateral shearing 431 with some boundary effect occurring near the substrate due to the specific process and parameters used and/or due to the compliant and/or elastic nature of the template material. FIG. 4D illustrates the state of the process after a single probe material 441 is deposited and the deposit is potentially planarized. FIG. 4E illustrates the state of the process after the template material is removed 451 leaving a completed or partially completed probe array 461 adhered to the substrate.

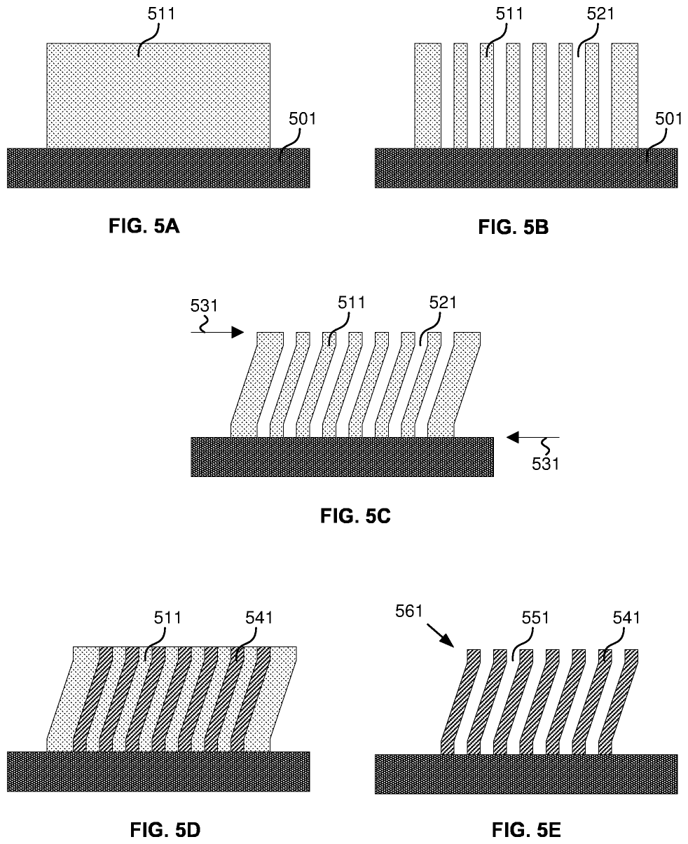

FIGS. 5A-5E illustrate various states of a process for forming a probe array according to a third embodiment of the invention. FIG. 5A illustrates the state of the process after a single layer of template material 511 is deposited or located over a substrate 501. FIG. 5B illustrates the state of the process after openings 521 for receiving a probe material are created. FIG. 5C illustrates the state of the process after the template is deformed by lateral shearing 531 with some boundary effect occurring near the substrate and near the top of the template due to the specific process and parameters used and/or due to the compliant and/or elastic nature of the template material. FIG. 5D illustrates the state of the process after a single probe material 541 is deposited. FIG. 5E illustrates the state of the process after the template material is removed 551, leaving a completed or partially completed probe array 561 adhered to the substrate.

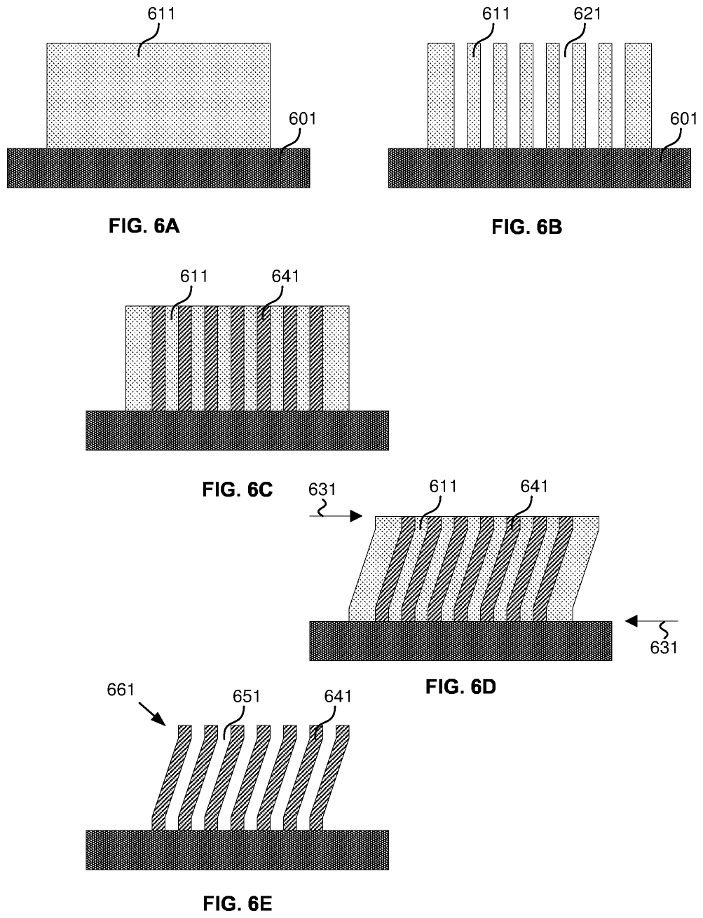

FIGS. 6A-6E illustrate various states of a process for forming a probe array according to a fourth array formation embodiment of the invention. FIG. 6A illustrates the state of the process after a single layer of template material 611 is deposited or located over a substrate 601. FIG. 6B illustrates the state of the process after openings 621 for receiving a probe material are created in the template material. FIG. 6C illustrates the state of the process after a single probe material 641 is deposited into the voids in the template (and potentially planarized). FIG. 6D illustrates the state of the process after the template and deposited probe material are deformed by lateral shearing 631 with some boundary effect occurring near the substrate and near the top of the template due to the specific process and parameters used and/or due to the compliant and/or elastic nature of the template material and probe material. FIG. 6E illustrates the state of the process after the template material is removed 651 leaving a completed or partially completed probe array 661 adhered to the substrate.

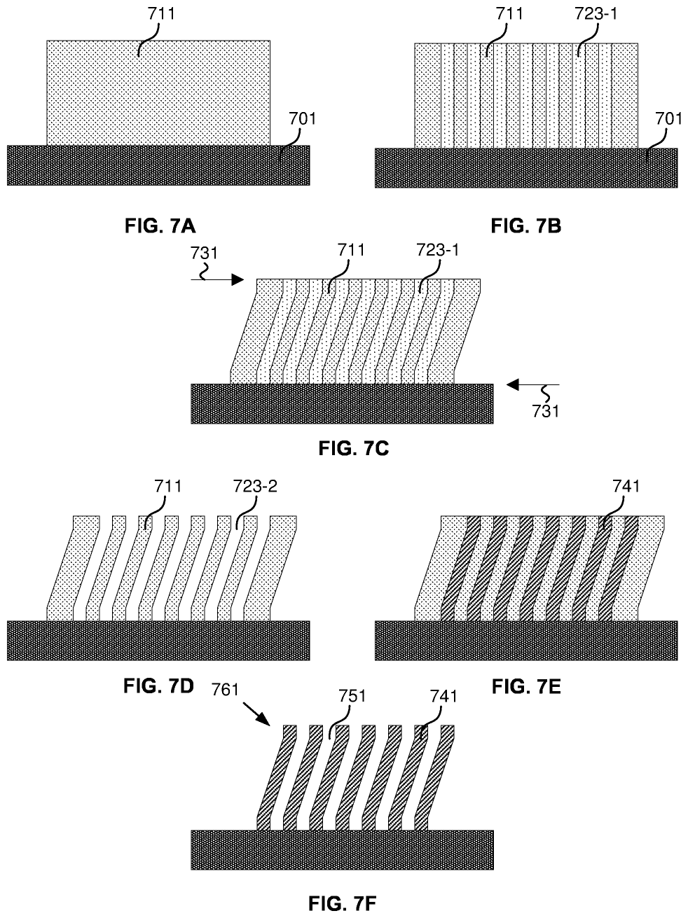

FIGS. 7A-7F illustrate various states of a process for forming a probe array according to a fifth array formation embodiment of the invention. FIG. 7A illustrates the state of the process after a single layer of template material 711 is deposited or located over a substrate 701. FIG. 7B illustrates the state of the process after latent openings 723-1 have been formed (i.e., locations that will eventually become openings for receiving a probe material), e.g. by exposing a photoresist but not developing it. FIG. 7C illustrates the state of the process after the template is deformed by lateral shearing 731 with some boundary effect occurring near the substrate and near the top of the template due to the specific process and parameters used and/or due to the compliant and/or elastic nature of the template material and probe material. FIG. 7D illustrates the state of the process after latent openings are converted to actualized openings or voids 723-2 by removal of material from the template corresponding to the latent openings that were initially created, e.g. by removing material of a negative photoresist or photopolymer that was not exposed or by removing material of a positive photoresist or polymer that was exposed or other material that underwent chemical breakdown or change as a result of initial exposure. FIG. 7E illustrates the state of the process after a single probe material 741 is deposited in the voids in the template material (and potentially planarized). FIG. 7F illustrates the state of the process after the remaining template material is removed 751 leaving a completed or partially completed probe array 761 adhered to the substrate.

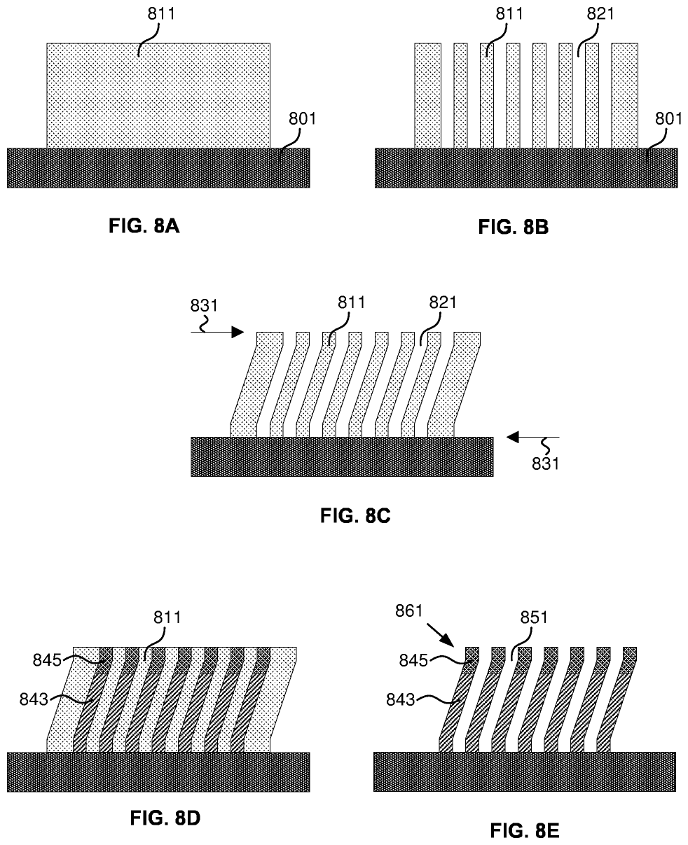

FIGS. 8A-8E illustrate various states of a process for forming a probe array according to a sixth array formation embodiment of the invention. FIG. 8A illustrates the state of the process after a single layer of template material 811 is deposited or located over a substrate 801. FIG. 8B illustrates the state of the process after openings 821 for receiving a probe material are created in the template material. FIG. 8C illustrates the state of the process after the patterned template is deformed by lateral shearing 831 with some boundary effects occurring near the substrate and near the top of the template due to the specific process and parameters used and/or due to the compliant and/or elastic nature of the template material. FIG. 8D illustrates the state of the process after a first probe material 843 (e.g. an elastic spring material) is deposited to partially fill the openings in the template material after which a second probe material 845 (e.g. a tip material) is deposited. FIG. 8E illustrates the state of the process after the template material is removed 851 leaving a completed or partially completed probe array 861 adhered to the substrate.

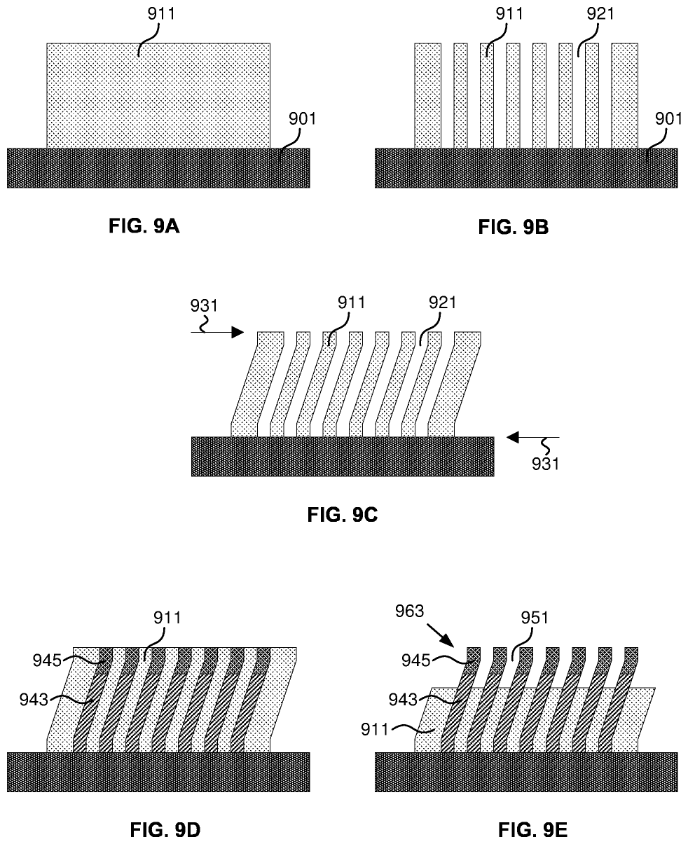

FIGS. 9A-9E illustrate various states of a process for forming a probe array according to a seventh array formation embodiment of the invention. FIG. 9A illustrates the state of the process after a single layer of template material 911 is deposited or located over a substrate 901. FIG. 9B illustrates the state of the process after openings 921 for receiving a probe material are created in the template material. FIG. 9C illustrates the state of the process after the template is deformed by lateral shearing 931 with some boundary effects occurring near the substrate and near the top of the template due to the specific process and parameters used and/or due to the compliant and/or elastic nature of the template material. FIG. 9D illustrates the state of the process after a first probe material 943 (e.g., an elastic spring material) is deposited to partially fill the plurality of openings in the template material after which a second probe material 945 (e.g., a tip material) is deposited to further fill the voids. FIG. 9E illustrates the state of the process after an upper portion of the template material is removed 951 leaving an array 963 of probes partially embedded in the template material which may, for example, provide for enhanced attachment of the probes to the substrate, improved probe life, minimization or elimination of probe-to-probe shorting, and/or increased spring force.

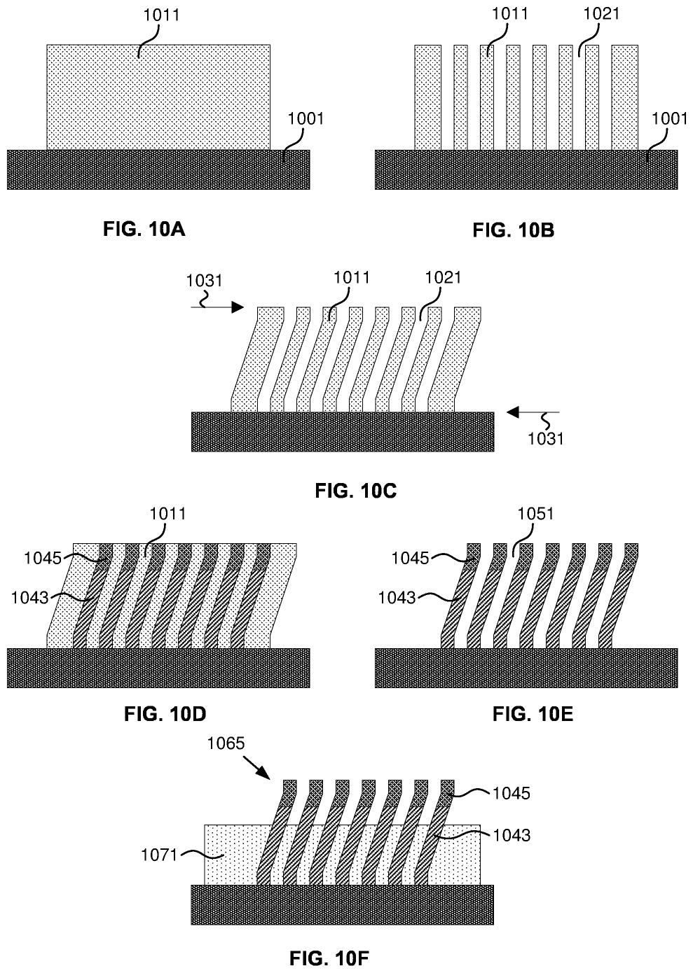

FIGS. 10A-10F illustrate various states of a process for forming a probe array according to an eighth array formation embodiment of the invention. FIG. 10A illustrates the state of the process after a single layer of template material 1011 is deposited or located over a substrate 1001. FIG. 10B illustrates the state of the process after openings 1021 for receiving a probe material are created in the template material. FIG. 10C illustrates the state of the process after the patterned template is deformed by lateral shearing 1031 with some boundary effects occurring near the substrate and near the top of the template due to the specific process and parameters used and/or due to the compliant and/or elastic nature of the template material. FIG. 10D illustrates the state of the process after a first probe material 1043 (e.g. an elastic spring material) is deposited to partially fill the plurality of openings after which a second probe material 1045 (e.g. a tip material) is deposited. FIG. 10E illustrates the state of the process after the template material is removed 1051. FIG. 10F illustrates the state of the process after a different material 1071 is deposited or applied to partially embed the probes wherein the embedded material is selected to have desirable properties for use in the final probe array or arrays wherein the partially embedded array 1065 may provide, for example, enhanced attachment of the probes to the substrate, improved probe life, minimization or elimination of probe-to-probe shorting, and/or increased or tailored spring force.

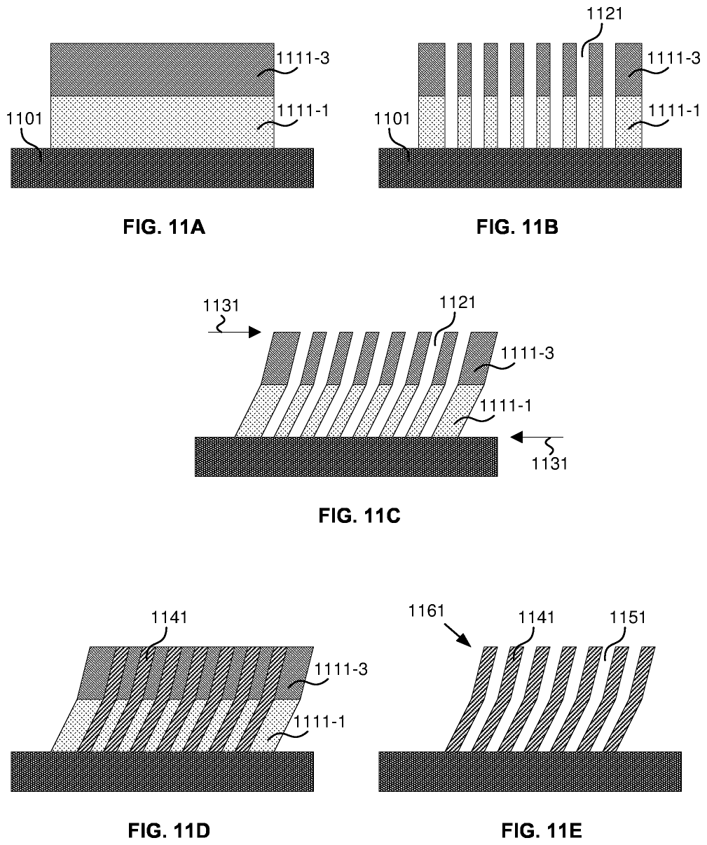

FIGS. 11A-11E illustrate various states of a process for forming a probe array according to a ninth array formation embodiment of the invention. FIG. 11A illustrates the state of the process after two different template materials have been deposited or located over a substrate 1101 (or a stack of two template materials has been applied to the substrate) wherein the upper material 1111-3 is less compliant than the lower material 1111-1 (i.e. the lower material bends or deforms more readily than does the upper material or alternatively the lower material will deform more than the upper material under a similar shear force). FIG. 11B illustrates the state of the process after openings 1121 through both materials are created (e.g. via a single exposure process and a single development process, via multiple exposure processes and/or development processes, via laser ablation, or the like). FIG. 11C illustrates the state of the process after the template is deformed by lateral shearing 1131 at two longitudinal levels (e.g. at the bottom of the template materials and at the top of the template materials as indicated by the arrows) with little boundary effect due to the specific process and parameters used and/or due to the compliant and/or elastic nature of the template material wherein the upper material undergoes less deformation (e.g. less orientation change) than does the lower material due to the difference in material compliance. FIG. 11D illustrates the state of the process after a single probe material 1141 is deposited into the deformed openings in the template materials and the deposit is potentially planarized. FIG. 11E illustrates the state of the process after the template material is removed 1151 leaving a completed or partially completed probe array 1161 adhered to the substrate.

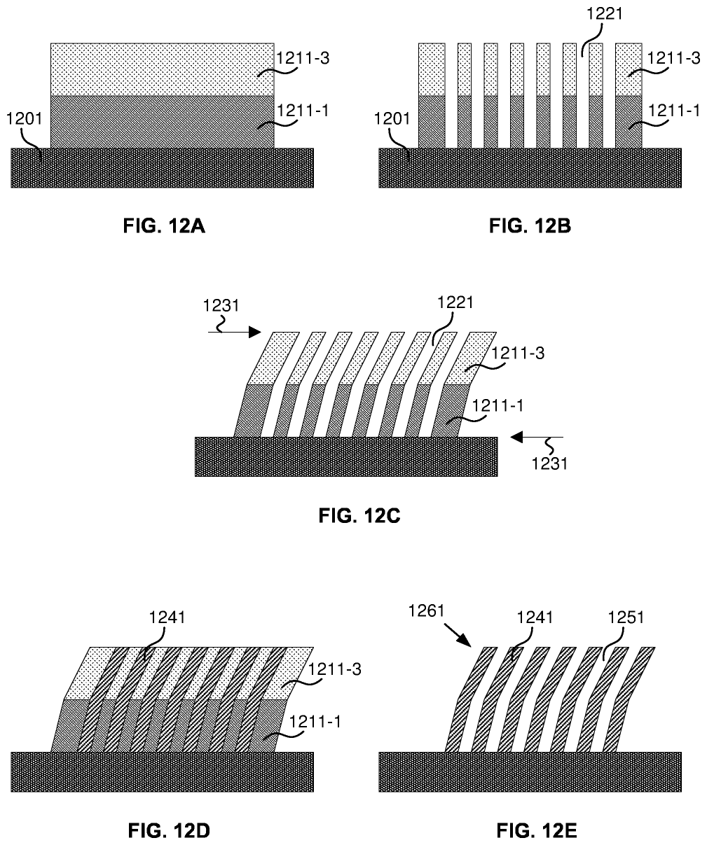

FIGS. 12A-12E illustrate various states of a process for forming a probe array according to a tenth array formation embodiment of the invention. FIG. 12A illustrates the state of the process after two different template materials have been deposited or located over a substrate 1201 (or a stack of two template materials has been applied to the substrate) wherein the upper material 1211-3 is more compliant than the lower material 1211-1 (i.e. the upper material bends or deforms more readily than does the lower material or alternatively the upper material will deform more than the lower material under a similar shear force). FIG. 12B illustrates the state of the process after openings 1221 through both materials are created (e.g. via a single exposure process and a single development process, via multiple exposure processes and/or development processes, via laser ablation, or the like). FIG. 12C illustrates the state of the process after the template is deformed by lateral shearing 1231 at two longitudinal levels as indicated by the arrows with little boundary effect due to the specific process and parameters used and/or due to the compliant and/or elastic nature of the template material wherein the upper material undergoes more deformation (or orientation change) than does the lower material due to the difference in material compliance. FIG. 12D illustrates the state of the process after a single probe material 1241 is deposited into the deformed openings and the deposit is potentially planarized. FIG. 12E illustrates the state of the process after the template material is removed 1251, leaving a completed or partially completed probe array 1261 adhered to the substrate.

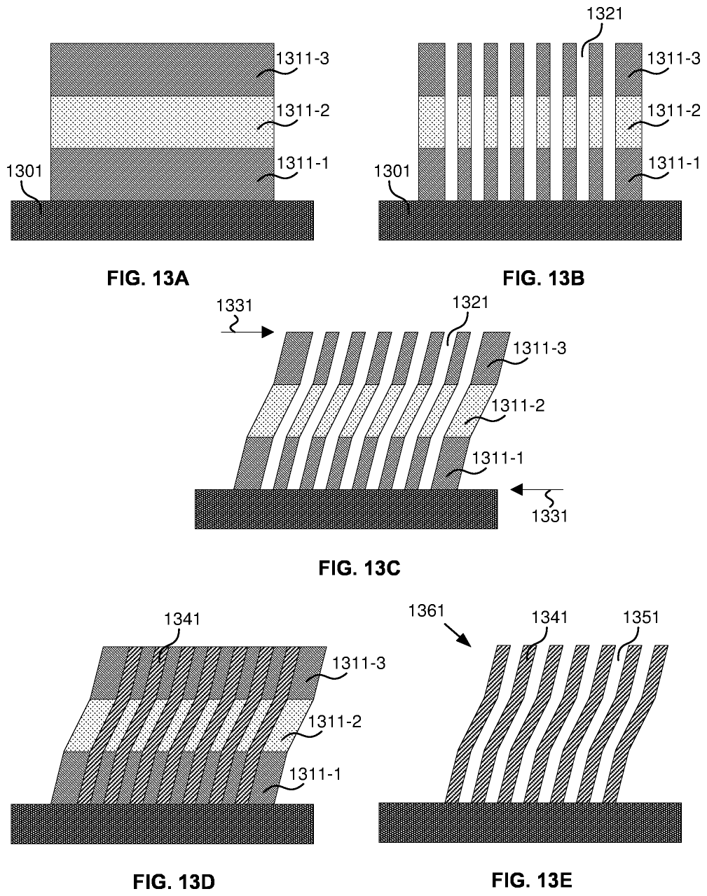

FIGS. 13A-13E illustrate various states of a process for forming a probe array according to an eleventh array formation embodiment of the invention. FIG. 13A illustrates the state of the process after three levels or layers of template material have been deposited or applied to a substrate 1301 wherein the lower 1311-1 and upper 1311-3 template materials are less compliant than the middle 1311-2 template material and wherein under a shear load, the middle material will tend to deform more than the upper and lower materials. FIG. 13B illustrates the state of the process after openings 1321 for receiving a probe material are created through all three levels of template material. FIG. 13C illustrates the state of the process after the template is deformed by lateral shearing 1331 at two longitudinal levels as indicated by the arrows with little boundary effect due to the specific process and parameters used and/or due to the compliant and/or elastic nature of the template materials wherein the middle material undergoes more deformation (or orientation change) than does either the lower or upper materials due to the differences in material compliance. FIG. 13D illustrates the state of the process after a single probe material 1341 is deposited into the deformed openings and the deposit is potentially planarized. FIG. 13E illustrates the state of the process after the template materials are removed 1351, leaving a completed or partially completed probe array 1361 or multiple arrays adhered to the substrate wherein the probes of the array include multiple intermediate (i.e. along a longitudinal axis of the array or axes of the arrays) bends or changes in orientation.

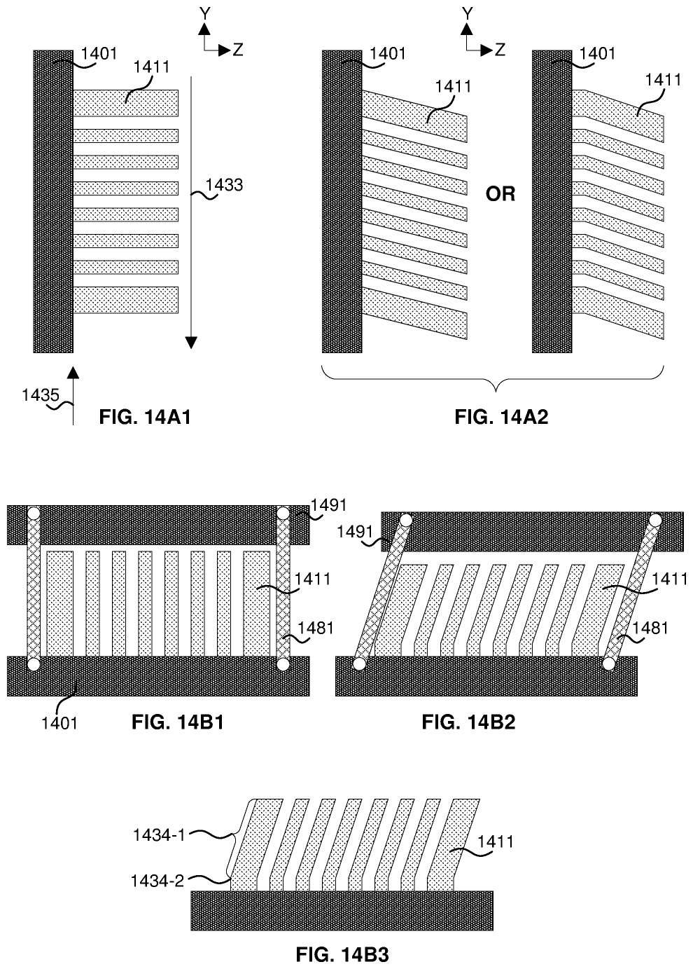

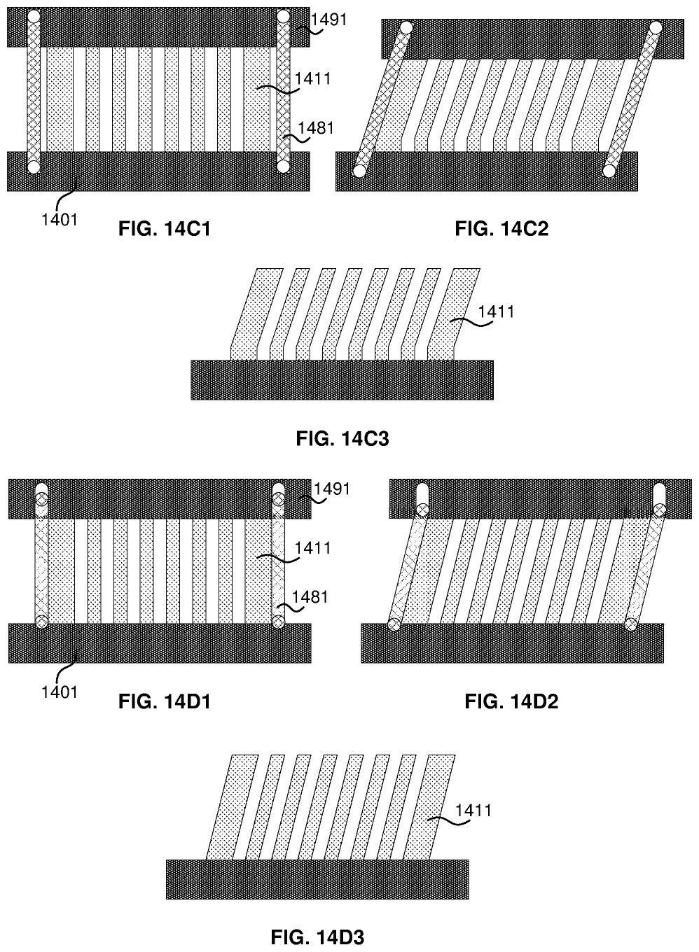

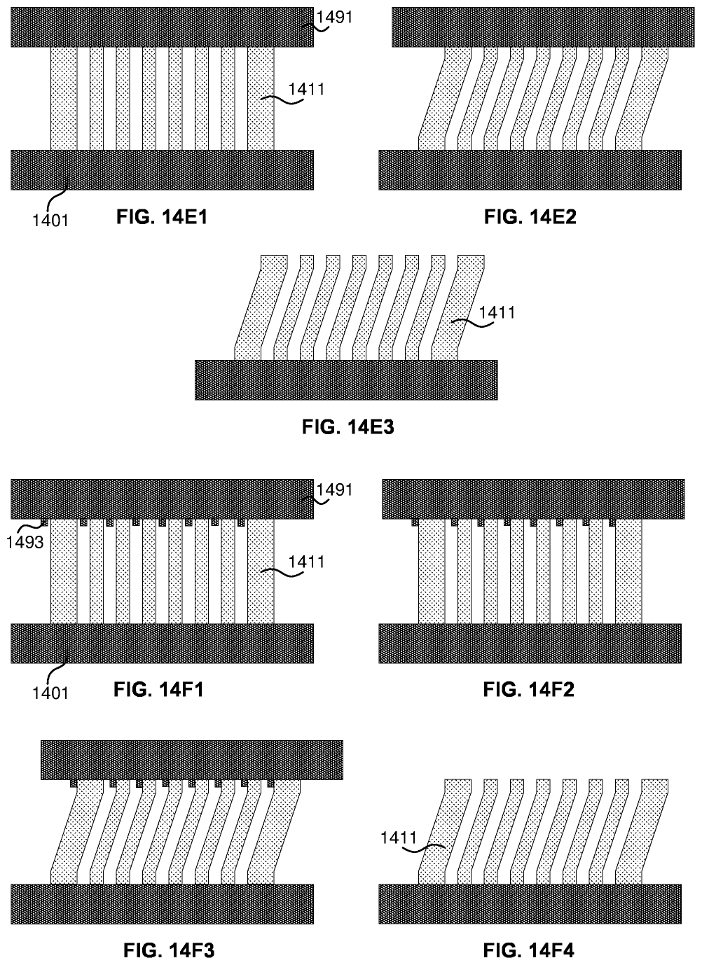

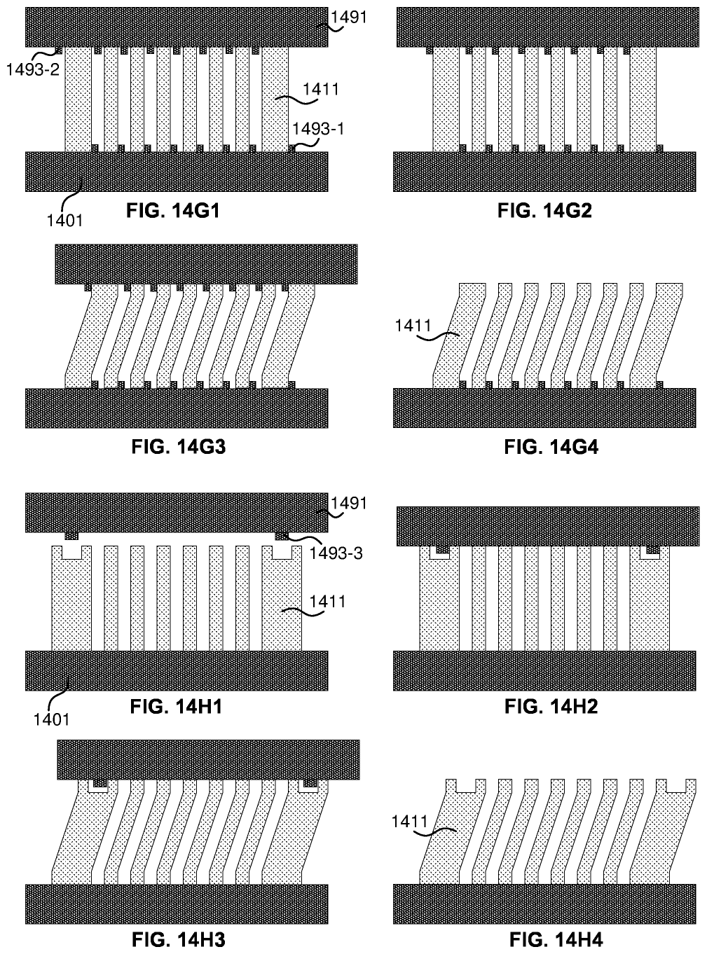

FIGS. 14A1-14H4 provide schematic illustrations of template deformation methods and tools according to eight different deformation methods and/or tooling embodiments wherein undeformed templates are shown along with anticipated results of deformation.

FIGS. 14A1 to 14A2 provide two examples of gravity induced deformation, wherein the force of gravity is in direction 1433 while the substrate 1401 is fixed along Z by a supporting structure (not shown) that provides upward force 1435, thus causing a net shearing force to be induced in the template material 1411 resulting in deformation thereof. FIG. 14A1 provides a patterned template prior to deformation. The left side of FIG. 14A2 provides a first example of deformation wherein no edge effects are shown, that is, there is no difference in deformation at the interface of the template compared to other locations along the longitudinal height of the probe (i.e. in the Z-direction) showing no edge effect on deformation at the boundary of the template and substrate while the right side of FIG. 14A2 shows the deformation with some edge effect in the form of a reduced amount of bending or reduced curvature due to the interface of the template material with the substrate. In other variations, the deformation in regions along Z away from the substrate may occur at a growing rate or may be limited by the upper edge (in Z at the lower right edge of the template) contacting a surface (not shown that inhibits further deformation).

FIGS. 14B1 to 14B3 provide an example of template deformation using a deformation tool having two rotary arms, or tilting side plates, 1481 on either side of the tool and a top plate 1491 where the rotary arms connect to the substrate 1401 and the top plate for rotational motion. FIG. 14B1 shows rotational deformation tool connected to the substrate along with a patterned template on a substrate prior to deformation. FIG. 14B2 shows the deformed template along with the rotated deformation template while FIG. 14B3 shows the plastically deformed template after removal of the deformation tool. Due, at least in part, to the spaced interface of the side arms, or plates, of the tool (particularly on the left edge of the template material), the deformation results in an interface edge 1434-1 and an interface bend 1434-2 effect where the template and substrate material meet and wherein the top deformation plate does not necessarily ever contact the upper surface of the template.

FIGS. 14C1 to 14C3 illustrate an example tool and method for template deformation similar to that of FIGS. 14B1 to 14B3 with the primary exception being that the upper plate 1491 of the deformation tool contacts the template material 1411 and may contribute to the deformation. FIG. 14C1 depicts the template, its substrate 1401, and deformation tooling prior to deformation. FIG. 14C2 provides an illustration of an example of the template, its substrate, and tooling after deformation. FIG. 14C3 provides an example of the template and its substrate after deformation and removal of the deformation tooling.

FIGS. 14D1 to 14D3 illustrate an example tool and method for template deformation similar to that of FIGS. 14C1 to 14C3 but with two primary differences: (1) there is no gap, or only a minimal gap between the edges of the tilting side plates 1481 such that upon deformation there is no, or at least minimal, interface edge effects, and (2) the top deformation plate 1491 attaches to the tilting plates with some ability for independent longitudinal movement such that the top deformation plate may aid in deforming the template material but with an additional degree of freedom that may help minimize any negative effects that might be associated with a rigid relationship between angle and height constraints that might otherwise exist. In some variations, position of the tilt arms within the slots in the top plate may be controlled based on tilt angle, may be linked so that the position in each slot is correlated, or may be otherwise set. FIG. 14D1 shows an example relationship of the substrate 1401, the template and the deformation tooling prior to deformation. FIG. 14D2 provides an example illustration of the substrate, template, and deformation tooling after deformation. FIG. 14D3 provides an example illustration of the substrate and template after deformation and removal of the deformation tooling wherein the lack of spacing between the template sides and edges of the tilting side plates results in reduced interface edge effects.

FIGS. 14E1 to 14E3 illustrate an example tool and method for template deformation wherein the deformation tooling consists of a top plate 1491 that is attached to, or otherwise made to engage, the top of the template material 1411 so that relative movement of the top plate and the substrate 1401 will cause template deformation. FIG. 14E1 illustrates an example substrate, template, and deformation tooling prior to deformation. FIG. 14E2 illustrates an example of the substrate, template deformation tooling after lateral displacement of the tooling and the substrate to provide a shear force between the top and bottom of the template to cause deformation wherein both the bottom and the top of the template show some level of interface effect on the deformation. FIG. 14E3 shows the template and its attached substrate after deformation and removal of the deformation tooling. In some variations of the example of FIGS. 14E1 to 14E3, lateral displacement may be accompanied by some longitudinal compression or the tool relative to the substrate or even, possibly, some longitudinal separation of the substrate and tool if bonding is sufficient or attachment of the tooling and the template material is sufficient. In some additional variations, separation of the tooling and the template material may occur by dissolving the tooling material, by use of temperature variation (e.g., heating or cooling) between the tooling material and the template material to weaken the bond, by cutting through the template material immediately below the tool. In some variations, the template may have openings extending longitudinally therethrough where the openings are laterally aligned with the openings in the template so as to allow deposition of probe material into the template openings through the tool and after deposition of such probe material or materials, the tooling and the template material may be removed together. In some embodiments, the extent of lateral movement of the tooling may or may not be identical to the final deformation of the template material as only a portion of the deformation may be associated with plastic deformation while the remaining portion may be associated with elastic deformation or other deformation that will be released upon removal of the tooling and as such, the level of lateral displacement of tooling may be greater than the final level of deformation. In other alternatives, when deposition of probe material will occur through openings in a deformation tool, no plastic deformation may be required as elastic deformation of template material followed by probe material deposition may be sufficient to form probes with a desired configuration. In such alternatives, after probe material deposition, the deformation tooling and some or all of the template material may be removed leaving a probe array with probes having a desired configuration and spacing and possibly with an intermediate material (e.g. retained template materials) located between portions of the probes particularly when the intermediate material is compliant or elastic or where the intermediate material has a shallow height and is present to enhance retention of the probes to the substrate. As with other embodiments noted herein, the above variations associated with this embodiment may be used in association with the other embodiments set forth herein to the extent they are compatible therewith and to the extent that appropriate changes are made as will be apparent to those skill in the art upon review of the teachings herein.

FIGS. 14F1 to 14F4 illustrate an example tool and method for template deformation similar to that of FIGS. 14E1 to 14E3 wherein the upper deformation tool plate 1491 includes engagement tabs 1493 configured for insertion to template openings that may be used in providing more uniform lateral deformation of the template material 1411 and which may or may not make use of adhesion between the upper deformation tool and the template material. FIG. 14F1 depicts an example state of the process after a substrate 1401 has received template material and openings have been formed in the template material and after an upper deformation tooling having insertion tabs configured for engaging the template openings has been laterally and longitudinally located. FIG. 14F2 depicts the state of the process prior to deformation but after relative shifting of the upper tool so that its tabs engage the right side of the openings. FIG. 14F3 depicts the state of the process after lateral shifting of the substrate and deformation plate moved laterally with respect to one another to cause deformation of the template material. FIG. 14F4 illustrates an example of the deformed template structure on the substrate after deformation and removal of the upper deformation tooling. In the present example, due to the tabs, the upper deformation plate need not be attached to the template material as it is believed that the tabs can provide adequate engagement to allow controlled deformation. In some alternatives, attachment can also be made to occur.

In some alternatives, not all openings need to receive a tab while in others, all or a portion of the openings may receive more than one tab (depending on the relative size and position of the tabs and the openings). In other alternatives, the tabs may not be longitudinally fixed in extended positions but may take the form of longitudinally extendible pins, and they may not be laterally positioned to specifically match the openings in the template and they may or may not have the same lateral shape as the openings. The pins may be spring loaded or independently and longitudinally adjustable to allow extension from the bottom of an upper tool plate and to allow retraction into the plate such that after lateral and longitudinal placement of the upper tool plate against or near the surface of the template, the pins may be made to extend from the bottom of the tool plate (to the extent they are not individually inhibited by interfering template material such that some portion of the pins enter openings in the template and upon lateral movement of the tool relative to the substrate, a portion of the pins aid in engagement to assist or cause lateral deformation of the template. In other variations, shallow holes may be formed in the template material, away from the probe material openings, into which tabs in the upper deformation plate extend to ensure engagement or possibly even interlocking. In some variations, probe formation holes or openings may be formed through the holes in the deformation plate after mounting the deformation plate onto existing template material or after locating template material between a longitudinal and laterally aligned substrate and deformation plate whereby after probe hole opening formation in the template material and after template deformation, probe material may be deposited. In further variations, probe material may be deposited prior to template deformation.

FIGS. 14G1 to 14G4 illustrate an example tool and method for template deformation similar to that of FIGS. 14F1 to 14F4 with the exception that the substrate also includes engagement tabs which are positioned in the openings in the template material that are intended to receive probe material.

FIG. 14G1 illustrates an example state of the process showing (1) a template with openings therein sitting on a substrate 1401 with tabs 1493-1 forming part of the upper surface of the substrate where the tabs extend into the openings such that a plate-like portion of the substrate supports the template material 1411 longitudinally while the tabs of the substrate can inhibit lateral motion of the bottom of the template material relative to the substrate, and (2) an upper deformation tool with a plate-like portion 1491 and tabs 1493-2 located on the bottom of the plate-like portion where the tabs can inhibit lateral motion of the top of template material relative to the upper deformation tool. In particular, in the state as shown in FIG. 14G1, the substrate tabs engage template material on the left side of the openings which means further rightward motion of the lower portion of the template material is inhibited at least in part by the tabs; however, since the tabs on the substrate are not engaged with the right side of the wall material of the opening, the tabs will not assist leftward lateral displacement of the template material relative to the substrate without an initial, but small, displacement of the template material. Since the tabs of the upper deformation plate are not shown as engaging either left or right sidewall material, they do not inhibit relative displacement in either direction until contact with a template wall occurs. As such slight lateral displacement of the template material relative to the tabs is necessary before the tabs of the upper deformation plate will contribute to lateral displacement inhibition. FIG. 14G2 illustrates the state of the process after slight rightward displacement of the upper deformation tool relative to the template material provides for lateral engagement of the tabs against the right sidewalls of the openings. FIG. 14G3 illustrates further lateral movement of the upper deformation tool to the right relative to the substrate such that deformation of the template occurs. FIG. 14G4 illustrates the state of the process after the upper deformation plate is removed leaving a plastically deformed template. In further steps (not shown), array formation could continue with probe material being deposited into the openings, with template material being removed in whole or in part, and with any additional array formation steps being performed. In some embodiment variations, deposition of probe material may have occurred while the upper deformation plate was still in place, thus allowing the deformation of the template material to be plastic, elastic, or of some combination of the two.

In some embodiment variations, the tabs on the substrate may be formed by a partial filling of the openings in the template material (which is adhered to the substrate) with probe material (e.g. to a height of under 10 ums to more than 100 ums) wherein after deformation, additional probe material could be deposited into the openings. In still other variations, probe material could be dispensed into the openings to the full height or even greater height if trimming (e.g., planarization) will be used to set the final height of the probe array and thereafter deformation could be made to occur. In other embodiment variations, the template material with holes may be transferred to a substrate that already includes tabs where the tabs may be conductive and eventually become part of the probes or provide enhanced probe support. In still other embodiments, template material may be located around the tabs on the substrate, and thereafter, openings in the template material may be formed corresponding to the intended probe locations which may coincide with tab locations. In other variations, the tab locations may intentionally be located to avoid probe opening locations wherein the template material simply surrounds and engages the tabs. In still further variations, the tabs may have reentrant features that interlock with the template material to form stronger attachment.

FIGS. 14H1 to 14H4 illustrate another example template tool and deformation method wherein the template includes portions with non-probe openings (e.g., blind openings or indents) that can be used to engage corresponding tabs, pins, bars, and the like on a deformation plate to aid in controlling relative lateral positioning of a surface of the template material and a deformation tool. FIG. 14H1 illustrates the state of the process after a template and deformation tooling are laterally aligned but not yet longitudinally engaged. FIG. 14H2 illustrates the state of the process prior to deformation but after longitudinal engagement of the tabs 1493-3 and openings and after relative shifting of the upper tool 1491 so that its tabs engage the right side of the openings or depressions. FIG. 14H3 illustrates the state of the process after further lateral displacement of the tooling relative to the substrate 1401 provides deformation of the template material 1411. FIG. 14H4 illustrates the state of the process after template deformation and removal of the upper deformation tool. In variations of the embodiment of FIGS. 14H1 to 14H4, the deformation plate may be engaged with but does not necessarily need to be attached to the top of the template. Similar non-bonding methods may be used for engaging the substrate and the template especially in embodiments where guide plates or other array structures will be used or where transfer from a deformation substrate to an array substrate is intended.

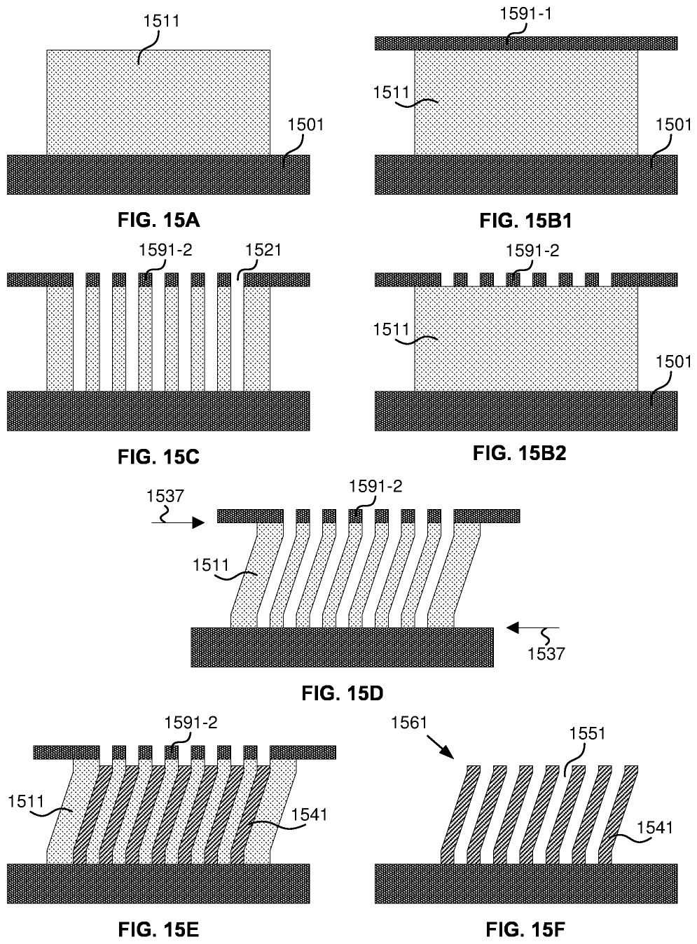

FIGS. 15A-15F illustrate various states of a process for forming a probe array according to a twelfth array formation embodiment of the invention wherein a deformation tool (or plate) is located on a layer of template material and then openings are made in both the deformation tool and the template material to define regions that will receive depositions of one or more probe materials after deformation of the template material has been completed. FIG. 15A illustrates the state of the process after a single layer template material 1511 is deposited or located over a substrate 1501. FIG. 15B1 illustrates a next and first alternative state of the process after a deformation tool without openings 1591-1 is attached to the upper portion of the template material while FIG. 15132 illustrates second alternative state of the process after a deformation tool with openings 1591-2 is attached to the upper portion of the template material. FIG. 15C illustrates the state of the process resulting from either forming openings 1521 through both the deformation tool and the template material of FIG. 15131 or through the template material only via the openings already existing in the deformation tool of FIG. 15B2 wherein the openings 1521 are intended to eventually receive deposition of one or more probe materials to form a plurality of probes for one or more arrays or subarrays. FIG. 15D illustrates the state of the process after the substrate and the upper deformation plate are shifted as indicated by arrows 1537 to deform the template material and provide a desired deformed template pattern with deformed openings for receiving probe material. FIG. 15E illustrates the state of the process after a single probe material 1541 is deposited into the openings wherein the deposition lacks a thickness to reach the deformation tool, though in variations of the embodiment, the deposited material may reach and even overcoat the deformation tool in which case a planarization process or other process may be used to set a controlled height of deposition. FIG. 15F illustrates the state of the process after the template material and upper deformation plate are removed, leaving a completed or partially completed probe array 1561 adhered to the substrate with gaps between the probes where template material was removed 1551.

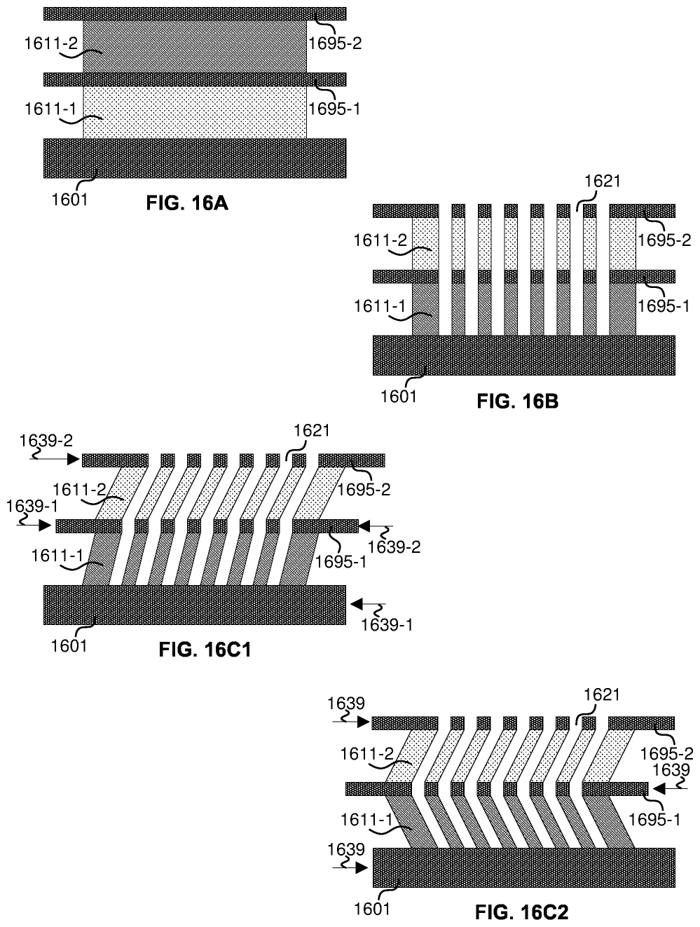

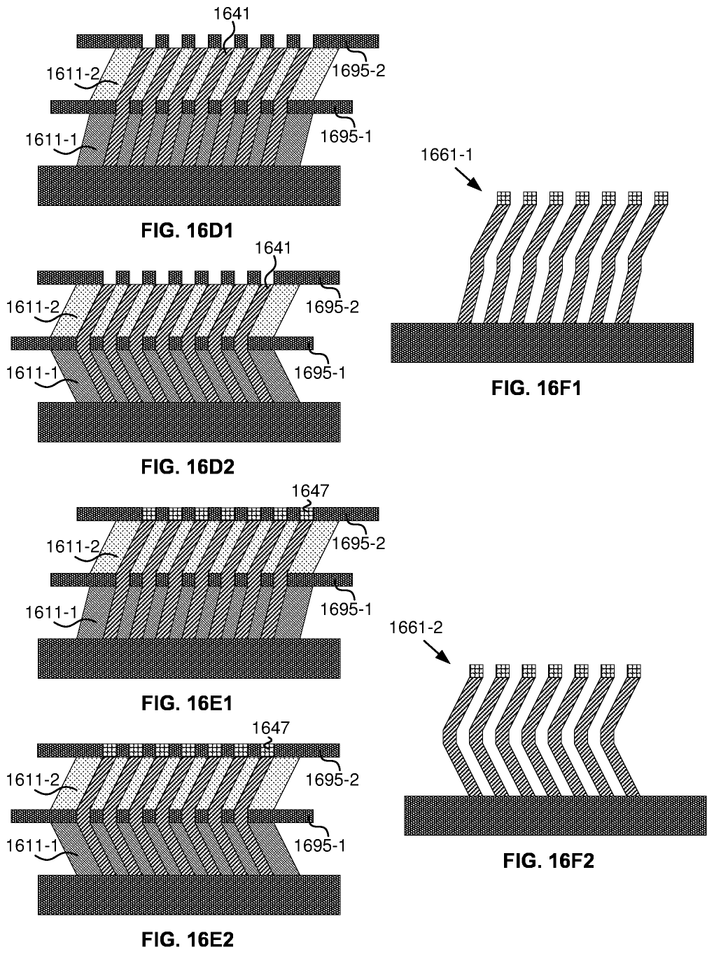

FIGS. 16A-16F2 illustrate various states of a process for forming a probe array according to a thirteenth array formation embodiment of the invention. FIG. 16A illustrates the state of the process after a number of processes or steps of have occurred including: (a) a first layer of template material 1611-1 is formed or located on a substrate 1601 wherein the substrate may or may not act as lower deformation tool depending on the types of deformation that are to occur, (b) an intermediate deformation tool 1695-1 is attached to the top of the first template material, (c) a second layer of template material 1611-2 (which may or may not be different from the first material) is formed on and adhered to the intermediate deformation tool, and (d) an upper deformation tool 1695-2 is attached to the second template material. FIG. 16B illustrates the state of the process after openings 1621 are formed through the deformation tools and the template materials wherein the openings are intended for receiving deposited probe material but may be used for other purposes in variations of the process. In some alternative embodiments, holes may have been formed in the template materials or the deformation tools prior to positioning, or prior to adding a subsequent structure or material thereon. FIG. 16C1 illustrates the state of the process for a first deformation example which results in probes with two levels of a right leaning configuration or tilt after the intermediate deformation tool (or plate) undergoes lateral displacement relative to the substrate as shown by the pair of arrows 1639-1 and the upper deformation tool (or plate) undergoes relative lateral displacement relative to the intermediate deformation tool as shown by the pair of arrows 1639-2. In some variations, the lateral displacement may occur simultaneously, they may occur one before the other, and one or both may be accompanied by relative longitudinal shifting as well. The relative lateral displacement may be completely controlled by the displacement forces and magnitudes used or they may be controlled by differences in stiffness of the two template materials, particularly when no lateral biasing is applied to the intermediate plate (e.g., if the intermediate plate functions primarily or solely as stiffening plate between the two materials to ensure controlled behavior at the interface of the two materials). In some variations, different amounts of over-displacement may be required when attempting plastic deformation of the different materials due to differences in plastic and elastic behavior of the materials should they be of different materials, be applied in different manner, or be of different relative heights. FIG. 16C2 illustrates the state of the process after a second deformation example, which is different from the example of FIG. 16C1, and which results in probes with a right facing C-shaped configuration (or left facing chevron shape) after the middle deformation tool is moved to the left relative to both the substrate and the upper deformation tool as indicated by the three arrows 1639. FIGS. 16D1 and 16D2 illustrates the state of the process after a single probe material 1641 is deposited into the two example deformed patterns of template material wherein FIG. 16D1 shows an array of right leaning probes while FIG. 16D2 shows an array of C-shaped or chevron shaped probes. FIGS. 16E1 and FIG. 16E2 illustrates the state of the process after an optional second deposit of probe material occurs to fill the openings in the upper deformation tool which may be a tip material 1647. In variations of this embodiment, the top of the first deposited probe material has not completely filled the template material and a second deposit of structural material may have been located completely or partially within the template material. In some embodiments, the deposited second material or even the deposited first probe material may have undergone shaping by physical means (machining, grinding, lapping, or the like), some other energetic means (e.g., laser cutting or ablation), or by a chemical or electrical means (e.g., etching, electrical discharge machining, reverse plating, or the like). FIGS. 16F1 and 16F2 show the state of the process after removal of the template material and the deformation tools wherein FIG. 16F1 shows the array 1661-1 of right leaning probes and FIG. 16F2 shows the array 1661-2 of C-shaped or chevron shaped probes, both having optional tip material located on the upper ends of the probes. In some embodiment variations, the deformation tools may have been retained as guide plates or other array structure and may have been inserted after removal of the deformation tools or even before placement of the first template material in a manner analogous to that taught in the '962 application (P-US405-A-MF).

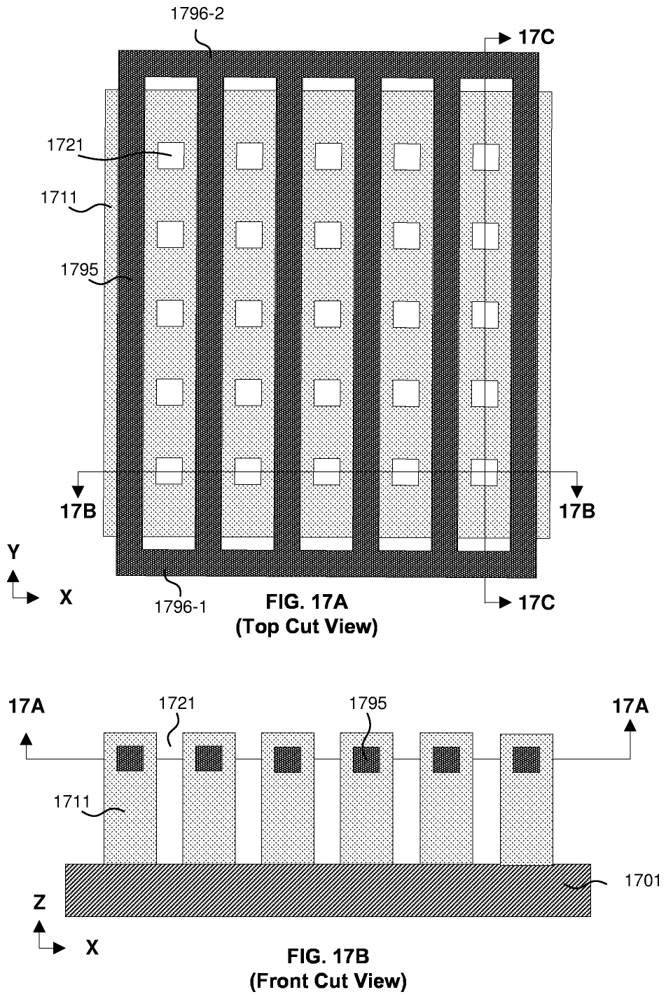

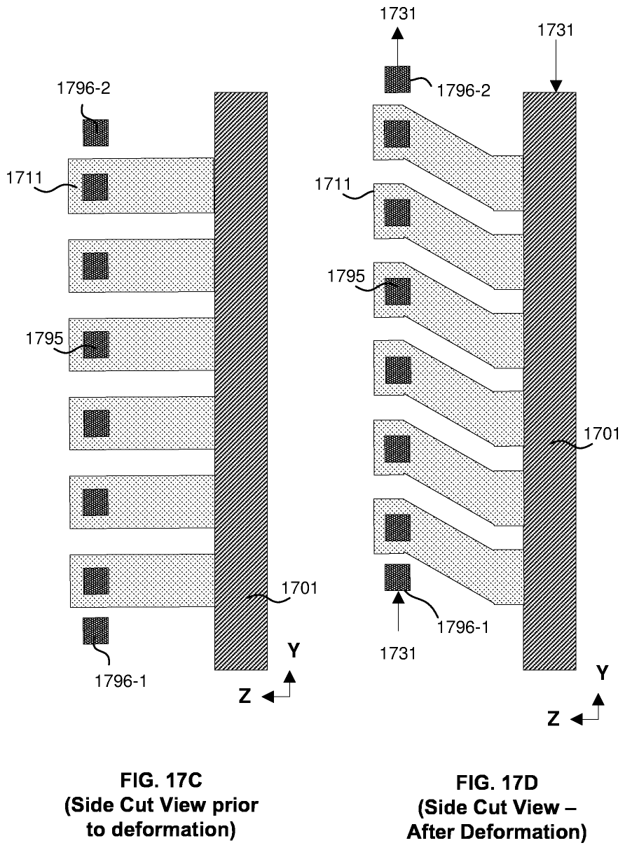

FIGS. 17A-17D illustrate another deformation tool 1795 and deformation method wherein the tool is embedded into template material 1711 at a desired longitudinal level such that deposited probe material will not contact the deformation tool. FIG. 17A shows a top cut view along lines 17A-17A of FIG. 17B wherein the deformation tool 1795 (with the exception of its handles 1796-1 and 1796-2) being surrounded by template material 1711 which includes twenty-five openings 1721 for receiving probe material wherein the deformation handles allow external forces 1731 to be applied to the tool without directly applying to the template material. It is believed that the deformation tool may aid in providing more uniform deformation of the template material so that openings therein will have more controlled and more uniform configurations from probe-to-probe. FIG. 17B shows a front cut view along line 17B-17B of FIG. 17A where the encapsulation of the deformation tool from above and below along the Z axis can be seen. FIG. 17C shows a side cut view along the line 17C-17C while FIG. 17D provides an illustration of the template of FIG. 17C after deformation occurs by pushing on handle 1796-1 and/or pulling on handle 1796-2 while pushing on the substrate 1701. After deformation, one or more probe materials may be deposited into the deformed template. Additional steps may be performed to finalize the probe array or otherwise prepare the array for usage, e.g., to remove all or part of the template material, to provide probe tip shaping, to insert a retention material around the probe to substrate interface, to add one or more guide plates, to remove the substrate or to replace the substrate with a different substrate (e.g. a space transformer), to form larger array structures by laterally tiling arrays with one another, to separate the array elements into multiple subarray elements for recombining in one or more different configurations, to heat treat the probes, to pre-bias the probes into working configurations, and the like.

Numerous alternatives to some of the above method embodiments and tooling embodiments have been noted above while numerous other alternatives or variations to all of the possible embodiments are possible and will be apparent to those of skill in the art upon review of the teachings herein. In some such alternative embodiments, the alternatives or variations noted with regard to one embodiment may be applied to the other embodiments, mutatis mutandis. In some such alternative embodiments, or variations, where multiple layers of photoresist are being used as template materials, patterning of the different levels of photoresist, and/or development of the different layers of photoresist may be performed in any functional order, e.g., exposure may occur after formation of each layer or after formation of all layers. Development may also occur layer-by-layer (particularly where a filling material will be added) or through all layers at the same time. Different layers may be planarized after formation, after incorporation of deformation tool material, after exposure, development, or deposition of probe material.

Other such alternative embodiments or variations may include, for example: (1) use of deformation tools that are deformation plates to which template material is attached or engaged for deformation purposes, (2) use of different numbers of the deformation plates or tools; (3) use of different longitudinal positioning of the deformation plates or tools; (4) use of deformation plates or tools with different sized holes; (5) use of longitudinal shifting of deformation tools during lateral shifting (e.g. to account for changing of height as tilting of template material occurs; (6) retention of one or more deformation tools as guide plates with such plates retained at their longitudinal deformation levels or moved to a different longitudinal levels; (7) two or more guide plates being added, or one or more guide plates being added along with a deformation tool being retained as a guide plate; (8) the substrate being removed, (9) a different substrate (e.g. a space transformer substrate) attached, directly or indirectly, to the top of probes or template material wherein the probes may be formed right-side up or upside down; (10) a different substrate (e.g. a space transformer) attached directly or indirectly to the bottom of the probes; (11) changing the order of performing operations or steps particularly when (a) the change in order has little or no impact on the overall process, or (b) the change in order offers a desired advantage which is believed to outweigh any negative impact, (12) dividing steps in more focused tasks or operations, (13) adding in additional steps, and (14) using modified or alternative steps.

Still other such alternative embodiments and variations may include, for example: (1) using alternative probe materials, sacrificial materials, and/or masking materials during the formation of one or more layers or portions of layers to allow for enhanced probes or array formation; (2) use of alternative probe configurations, (3) incorporating probes having different longitudinal starting positions or ending positions, (4) providing probes with special contact tips or mounting ends with special shapes or formed from special material; (5) use of probes with contact tips on each end as opposed to one contact tip and one mounting end; (6) bottoms of probes not remaining attached to a substrate; (7) regions between probes being partially or completely filled with dielectric material, for example, a compressible material to aid in providing elastic force or to inhibit or reduce risk of shorting between closely spaced probes upon deflection or a more rigid material that aids to ensure that probe remain bonded and electrically connect to a substrate such as a space transformer; (8) probe arrays having uniform spacings between all probes; (9) probe arrays having gaps in probe positions; (10) probe arrays having probes located with non-uniform spacings; (11) probe arrays having probe tips configured in one-dimensional configurations (N×1); (12) probe arrays having probe tips configured in two-dimensional arrays (N×M); (13) one or two dimensional arrays having tips located at more than one longitudinal plane; (14) arrays having only a small number of probes, e.g. under ten, a moderate number of probes, e.g. tens to hundreds, a large number of probes, e.g. hundreds to thousands, or even a very large number of probes, e.g. from thousands to tens-of-thousands or more; (15) probes formed from as little as one layer or as many as tens of layers, or more, (16) probes formed from planarized layers or non-planarized layers, (17) layers including sacrificial material of a variety of types or using no sacrificial material; (18) arrays including guide plates that were not deformation tools; (19) using deformation tools that were initially inserted at longitudinal deformation levels, (20) removing a build substrate in favor of insertion or formation of one or more additional deformation tools for use in array formation or guide plates for use in final array configurations, (21) using heat treatments or other operations to modify the material properties of the probes or template material (e.g. to reduce yield strength or make it more uniform prior to deformation and/or to increase yield strength or improve spring properties after deformation); and/or (22) composite formation of probe arrays where a portion of a longitudinal height of the array is formed with template deformation methods as describe herein along with one or more of (a) a layer-by-layer patterning to obtain desired probe configurations, (b) a deformation based patterning to obtain desired probe configurations using deformation plates as taught in the '680 application (P-US407-A-MF), (c) a deformation based patterning to obtain desired probe configurations using stretching or longitudinal tensioning methods as taught in the '888 application (P-US388-A-MF).

Further alternative embodiments may provide probe arrays with probes having smooth curved configurations as opposed to substantially straight configurations with periodic bends which might be achieved using some of the embodiments set forth above. Such arrays may be formed, as noted above, using multiple pairs of deformation tools either operating in parallel or in series to force multiple bends along the longitudinal length of the probes or by use of stacked layers or levels of template material with the different levels having tailored yield strengths or compliances such that properly applied lateral displacements at selected longitudinal levels will produce templates with curved configurations. In some embodiments, a temperature differential may be applied between the one deformation level (e.g., such as the top of the template material) and at another level (e.g., such as the bottom of the template material) so as to form a temperature-based variation in yield strength or deformability of the material so that when lateral displacement occurs different levels of the template will provide smoothly varying changes in compliance and deformation. In some embodiments, deformation tools may include heating elements to directly apply a desired temperature or amount of heat to the template material.

In still other embodiments within a single type of template material (e.g. a particular type of photoresist material) different properties may be induced in the material by application of different parameters that control yield strength and compliance. For example, for a photoresist, different amounts of baking (e.g., time, temperature, and/or environment), different amounts of exposure (e.g., time, quantity and/or environment), different amounts solvent or developer (e.g., concentration, application area, temperature, and/or absorption time) can change the chemical and mechanical properties of the photoresist. Temperature, locations of openings, size of openings, depth of openings, opening type (latent, actualized, or filled with probe material or filled temporarily other materials), distribution of photo absorbers or other additives can also impact effective yield strength or compliance of the photoresist. By controlling these parameters, and potentially others that will be apparent to those of skill in the art upon review of the teaching herein, smooth variations in material compliance with longitudinal height can be achieved and utilized to create smoothly deformed templates and patterned holes. When a requirement for a reversal in bending direction occurs, a properly located deformation tool or template contact location may be used to reverse a direction of bending. As such, through the teachings set forth herein, deformation templates of desired configuration can be created and used to form probe arrays of desired configuration with reduced cost and time and with significant decoupling of cost, time, and formation difficulty from the probe count in such arrays.

### Further Comments and Conclusions

Various other embodiments of the present invention exist. Some of these embodiments may be based on a combination of the teachings herein with various teachings incorporated herein by reference. For example, some other embodiments, or embodiment variations may be derived, mutatis mutandis, from the generalized embodiments, specific embodiments, and alternatives set forth in previously referenced U.S. patent application Ser. No. 17/240,962 (P-US405-A-MF) by Lockard, et al., U.S. patent application Ser. No. 17/384,680 (P-US407-A-MF) by Yaglioglu, and U.S. Provisional Patent Application No. 63/064,888 (P-US388-A-MF) by Lockard, et al.

Various embodiments of various aspects of the invention are directed to formation of three-dimensional structures from materials, some, or all, of which may be electrodeposited or electroless deposited (as illustrated in FIGS. 1A-1I and as discussed in various patents and patent applications incorporated herein by reference). Some of these structures may be formed from a single build level (e.g. a planarized layer) that is formed from one or more deposited materials while others are formed from a plurality of build levels, each generally including at least two materials (e.g. two or more layers, five or more layers, and even ten or more layers). In some embodiments, layer thicknesses may be as small as one micron or as large as one hundred to two hundred microns. In still other embodiments, layers may be up to five hundred microns, one millimeter, even multiple millimeters (e.g. 3, 5, 7, 10 mm, or more). In other embodiments, thinner layers may be used. In still other embodiments, layer thickness may be varied during formation of different levels of the same structure. In some embodiments, microscale structures have lateral features positioned with 0.1-10 micron level precision and minimum feature sizes on the order of microns to tens of microns. In other embodiments, structures with less precise feature placement and/or larger minimum features may be formed. In still other embodiments, higher precision and smaller minimum feature sizes may be desirable. In the present application, meso-scale and millimeter-scale have the same meaning and refer to devices that may have one or more dimensions that may extend into the 0.1-50 millimeter range, or somewhat larger, and features positioned with a precision in the 0.1 micron to 100 micron range and with minimum feature sizes on the order of several microns to hundreds of microns.

Some fabrication embodiments may not use any blanket deposition process. Some embodiments may use selective deposition processes or blanket deposition processes on some layers that are not electrodeposition processes. Some embodiments may use nickel or nickel-cobalt as a structural material while other embodiments may use different materials. For example, preferred spring materials include nickel (Ni), copper (Cu), beryllium copper (BeCu), nickel phosphorous (Ni—P), tungsten (W), aluminum copper (Al—Cu), steel, P7 alloy, palladium, palladium-cobalt, silver, molybdenum, manganese, brass, chrome, chromium copper (Cr—Cu), and combinations of these. Some embodiments may use copper as the structural material with or without a sacrificial material. Some embodiments, for example, may use nickel, nickel-phosphorous, nickel-cobalt, palladium, palladium-cobalt, gold, copper, tin, silver, zinc, solder, rhodium, rhenium as structural materials while other embodiments may use different materials. Some embodiments, for example, may use copper, tin, zinc, solder or other materials as sacrificial materials. Some embodiments may use different structural materials on different layers or on different portions of single layers. Some embodiments may remove a sacrificial material while other embodiments may not. Some embodiments may use photoresist, polyimide, glass, ceramics, other polymers, and the like as dielectric structural materials.

Structural or sacrificial dielectric materials may be incorporated into embodiments of the present invention in a variety of different ways. Such materials may form a third material or higher deposited material on selected layers or may form one of the first two materials deposited on some layers. Additional teachings concerning the formation of structures on dielectric substrates and/or the formation of structures that incorporate dielectric materials into the formation process and possibly into the final structures as formed are set forth in a number of patent applications filed Dec. 31, 2003: (1) U.S. Patent Application No. 60/534,184 (P-US032-A-SC), which is entitled “Electrochemical Fabrication Methods Incorporating Dielectric Materials and/or Using Dielectric Substrates”; (2) U.S. Patent Application No. 60/533,932 (P-US033-A-MF), which is entitled “Electrochemical Fabrication Methods Using Dielectric Substrates”; (3) U.S. Patent Application No. 60/534,157 (P-US041-A-MF), which is entitled “Electrochemical Fabrication Methods Incorporating Dielectric Materials”; (4) U.S. Patent Application No. 60/533,891 (P-US052-A-MF), which is entitled “Methods for Electrochemically Fabricating Structures Incorporating Dielectric Sheets and/or Seed layers That Are Partially Removed Via Planarization”; and (5) U.S. Patent Application No. 60/533,895 (P-US070-B-MF), which is entitled “Electrochemical Fabrication Method for Producing Multi-layer Three-Dimensional Structures on a Porous Dielectric”. These patent filings are each hereby incorporated herein by reference as if set forth in full herein.

Additional patent filings that provide, intra alia, teachings concerning incorporation of dielectrics into electrochemical fabrication processes include: (1) U.S. patent application Ser. No. 11/139,262 (P-US144-A-MF), filed May 26, 2005, now U.S. Pat. No. 7,501,328, by Lockard, et al., and which is entitled “Methods for Electrochemically Fabricating Structures Using Adhered Masks, Incorporating Dielectric Sheets, and/or Seed Layers that are Partially Removed Via Planarization”; (2) U.S. patent application Ser. No. 11/029,216 (P-US128-A-MF), filed Jan. 3, 2005 by Cohen, et al., now abandoned, and which is entitled “Electrochemical Fabrication Methods Incorporating Dielectric Materials and/or Using Dielectric Substrates”; (3) U.S. patent application Ser. No. 11/028,957 (P-US127-A-SC), by Cohen, which was filed on Jan. 3, 2005, now abandoned, and which is entitled “Incorporating Dielectric Materials and/or Using Dielectric Substrates”; (4) U.S. patent application Ser. No. 10/841,300 (P-US099-A-MF), by Lockard et al., which was filed on May 7, 2004, now abandoned, and which is entitled “Methods for Electrochemically Fabricating Structures Using Adhered Masks, Incorporating Dielectric Sheets, and/or Seed Layers that are Partially Removed Via Planarization”; (5) U.S. patent application Ser. No. 10/841,378 (P-US106-A-MF), by Lembrikov et al., which was filed on May 7, 2004, now U.S. Pat. No. 7,527,721, and which is entitled “Electrochemical Fabrication Method for Producing Multi-layer Three-Dimensional Structures on a Porous Dielectric; (6) U.S. patent application Ser. No. 11/325,405 (P-US152-A-MF), filed Jan. 3, 2006 by Dennis R. Smalley, now abandoned, and entitled “Method of Forming Electrically Isolated Structures Using Thin Dielectric Coatings”; (7) U.S. patent application Ser. No. 10/607,931 (P-US075-A-MG), by Brown, et al., which was filed on Jun. 27, 2003, now U.S. Pat. No. 7,239,219, and which is entitled “Miniature RF and Microwave Components and Methods for Fabricating Such Components”, (8) U.S. patent application Ser. No. 10/841,006 (P-US104-A-MF), by Thompson, et al., which was filed on May 7, 2004, now abandoned, and which is entitled “Electrochemically Fabricated Structures Having Dielectric or Active Bases and Methods of and Apparatus for Producing Such Structures”; (9) U.S. patent application Ser. No. 10/434,295 (P-US061-A-MG), by Cohen, which was filed on May 7, 2003, now abandoned, and which is entitled “Method of and Apparatus for Forming Three-Dimensional Structures Integral With Semiconductor Based Circuitry”; and (10) U.S. patent application Ser. No. 10/677,556 (P-US081-A-MF), by Cohen, et al., filed Oct. 1, 2003, now abandoned, and which is entitled “Monolithic Structures Including Alignment and/or Retention Fixtures for Accepting Components”. These patent filings are each hereby incorporated herein by reference as if set forth in full herein.

Some embodiments may employ diffusion bonding or the like to enhance adhesion between successive layers of material. Various teachings concerning the use of diffusion bonding in electrochemical fabrication processes are set forth in U.S. patent application Ser. No. 10/841,382 (P-US102-A-SC), which was filed May 7, 2004 by Cohen et al., now abandoned, which is entitled “Method of Electrochemically Fabricating Multilayer Structures Having Improved Interlayer Adhesion” and which is hereby incorporated herein by reference as if set forth in full. This application is hereby incorporated herein by reference as if set forth in full.

The patent applications and patents set forth below are hereby incorporated by reference herein as if set forth in full. The teachings in these incorporated applications can be combined with the teachings of the instant application in many ways: For example, enhanced methods of producing structures may be derived from some combinations of teachings, enhanced structures may be obtainable, enhanced apparatus may be derived, enhanced methods of using may be implemented, and the like.

| U.S. Pat App No., Filing Date | |
|---|---|
| U.S. App Pub No., Pub Date | |
| U.S. Patent No., Pub Date | First Named Inventor, Title |
| 10/271,574 - Oct. 15, 2002 | Cohen, “Methods of and Apparatus for Making High Aspect |
| 2003-0127336 - Jul. 10, 2003 | Ratio Microelectromechanical Structures” |
| 7,288,178 - Oct. 30, 2007 | |
| 10/387,958 - Mar. 14, 2003 | Cohen, “Electrochemical Fabrication Method and |
| 2003-022168 - Dec. 4, 2003 | Application for Producing Three-Dimensional Structures |
| — | Having Improved Surface Finish” |
| 10/434,289 - May 7, 2003 | Zhang, “Conformable Contact Masking Methods and |
| 2004-0065555 - Apr. 8, 2004 | Apparatus Utilizing In Situ Cathodic Activation of a |
| — | Substrate” |
| 10/434,294 - May 7, 2003 | Zhang, “Electrochemical Fabrication Methods With |
| 2004-0065550 - Apr. 8, 2004 | Enhanced Post Deposition Processing” |
| — | |
| 10/434,315 - May 7, 2003 | Bang, “Methods of and Apparatus for Molding Structures |
| 2003-0234179 - Dec. 25, 2003 | Using Sacrificial Metal Patterns” |
| 7,229,542 - Jun. 12, 2007 | |
| 10/434,494 - May 7, 2003 | Zhang, “Methods and Apparatus for Monitoring Deposition |
| 2004-0000489 - Jan. 1, 2004 | Quality During Conformable Contact Mask Plating |
| — | Operations” |
| 10/677,498 - Oct. 1, 2003 | Cohen, “Multi-cell Masks and Methods and Apparatus for |
| 2004-0134788 - Jul. 15, 2004 | Using Such Masks To Form Three-Dimensional Structures” |
| 7,235,166 - Jun. 26, 2007 | |
| 10/697,597 - Oct. 29, 2003 | Lockard, “EFAB Methods and Apparatus Including Spray |
| 2004-0146650 - Jul. 29, 2004 | Metal or Powder Coating Processes” |
| — | |
| 10/724,513 - Nov. 26, 2003 | Cohen, “Non-Conformable Masks and Methods and |
| 2004-0147124 - Jul. 29, 2004 | Apparatus for Forming Three-Dimensional Structures” |
| 7,368,044 - May 6, 2008 | |
| 10/724,515 - Nov. 26, 2003 | Cohen, “Method for Electrochemically Forming Structures |
| 2004-0182716 - Sep. 23, 2004 | Including Non-Parallel Mating of Contact Masks and |
| 7,291,254 - Nov. 6, 2007 | Substrates” |
| 10/830,262 - Apr. 21, 2004 | Cohen, “Methods of Reducing Interlayer Discontinuities in |
| 2004-0251142 - Dec. 16, 2004 | Electrochemically Fabricated Three-Dimensional Structures” |
| 7,198,704 - Apr. 3, 2007 | |
| 10/841,100 - May 7, 2004 | Cohen, “Electrochemical Fabrication Methods Including Use |
| 2005-0032362 - Feb. 10, 2005 | of Surface Treatments to Reduce Overplating and/or |
| 7,109,118 - Sep. 19, 2006 | Planarization During Formation of Multi-layer Three- |
| | Dimensional Structures” |
| 10/841,347 - May 7, 2004 | Cohen, “Multi-step Release Method for Electrochemically |
| 2005-0072681 - Apr. 7, 2005 | Fabricated Structures” |
| — | |
| 10/949,744 - Sep. 24, 2004 | Lockard, “Multi-Layer Three-Dimensional Structures Having |
| 2005-0126916 - Jun. 16, 2005 | Features Smaller Than a Minimum Feature Size Associated |
| 7,498,714 - Mar. 3, 2009 | with the Formation of Individual Layers” |
| 12/345,624 - Dec. 29, 2008 | Cohen, “Electrochemical Fabrication Method Including |
| — | Elastic Joining of Structures” |
| 8,070,931 - Dec. 6, 2011 | |
| 14/194,564 - Feb. 28, 2014 | Kumar, “Methods of Forming Three-Dimensional Structures |
| 2014-0238865 - Aug. 28, 2014 | Having Reduced Stress and/or Curvature” |
| 9,540,233 - Jan. 10, 2017 | |
| 14/720,719 - May 22, 2015 | Veeramani, “Methods of Forming Parts Using Laser |
| — | Machining” |
| 9,878,401 - Jan. 30, 2018 | |
| 14/872,033 - Sep. 30, 2015 | Le, “Multi-Layer, Multi-Material Microscale and Millimeter |
| — | Scale Batch Part Fabrication Methods Including |
| — | Disambiguation of Good Parts and Defective Parts” |

It will be understood by those of skill in the art that additional operations may be used in variations of the above presented method of making embodiments. These additional operations may, for example, perform cleaning functions (e.g. between the primary operations) discussed herein or discussed in the various materials incorporated herein by reference, they may perform activation functions and monitoring functions, and the like.

It will also be understood that the probe elements of some aspects of the invention may be formed with processes which are very different from the processes set forth herein, and it is not intended that structural aspects of the invention need to be formed by only those processes taught herein or by processes made obvious by those taught herein.

Though various portions of this specification have been provided with headers, it is not intended that the headers be used to limit the application of teachings found in one portion of the specification from applying to other portions of the specification. For example, alternatives acknowledged in association with one embodiment are intended to apply to all embodiments to the extent that the features of the different embodiments make such applications functional and do not otherwise contradict or remove all benefits of the adopted embodiment. Various other embodiments of the present invention exist. Some of these embodiments may be based on a combination of the teachings set forth herein with various teachings incorporated herein by reference.

It is intended that any aspects of the invention set forth herein represent independent invention descriptions which Applicant contemplates as full and complete invention descriptions that Applicant believes may be set forth as independent claims without need of importing additional limitations or elements, from other embodiments or aspects set forth herein, for interpretation or clarification other than when explicitly set forth in such independent claims once written. It is also understood that any variations of the aspects set forth herein represent individual and separate features that may form separate independent claims, be individually added to independent claims, or added as dependent claims to further define an invention being claimed by those respective dependent claims should they be written.

Though the present application has been focused on probe array formation, the methods and tooling set forth herein may have application to formation of other microscale or mesoscale structures and arrays of such structures.

In view of the teachings herein, many further embodiments, alternatives in design and uses of the embodiments of the instant invention will be apparent to those of skill in the art. As such, it is not intended that the invention be limited to the particular illustrative embodiments, alternatives, and uses described above but instead that it be solely limited by the claims presented hereafter.

I claim:

1. A method for forming a probe array, comprising:
(a) providing a substrate;
(b) locating at least one deformable template material directly or indirectly on the substrate or on a previously located template material, wherein the at least one template material has a bottom and a top and extends in a longitudinal direction from the bottom to the top with the bottom located closer to the substrate than the top;
(c) patterning the at least one deformable template material to form a plurality of openings that extend in the longitudinal direction;
(d) exerting a lateral shearing displacement by application of a lateral shearing force between at least two longitudinal levels of at least one of the at least one template material to deform the at least one of the at least one template material to create a deformed template that results in at least a portion of the plurality of openings being deformed to become deformed openings having orientation changes relative to the openings prior to deformation; and
(e) depositing at least one probe material into the deformed openings in the deformed template to form probes for the probe array.

2. The method of claim 1 wherein the deformed template is, at least in part, plastically deformed.

3. The method of claim 1 wherein the deformed template is initially provided with a larger deformation that is reduced, at least in part, upon removal of the shearing force that applied the lateral displacement due to the presence of at least a portion of the deformation being caused by elastic deformation.

4. The method of claim 1 wherein the probe array is put to use with at least a portion of the at least one template material remaining in place.

5. The method of claim 4 wherein the portion of the template material that remain in place provides an elastic response to deformation during use of the probe array.

6. The method of claim 1 wherein substantially all of the at least one template material is removed from the array before putting the probe array to use.

7. The method of claim 1 wherein the deformation of the template results in each of a plurality of probes having at least one straight but angled segment.

8. The method of claim 1 wherein the deformation of the template results in each of a plurality of probes having at least two straight but angled segments.

9. The method of claim 1 wherein the deformation of the template results in each of a plurality of probes having at least two straight but angled segments that are directed in at least partially opposing lateral directions.

10. The method of claim 1 wherein the deformation of the template results in each of a plurality of probes having at least two straight but angled segments that lie in at least two different planes that each include an array normal.

11. The method of claim 1 wherein the deformation of the template results in each of a plurality of probes having at least one curved segment.

12. The method of claim 1 wherein the deformation of the template results in each of a plurality of probes having at least curved segments located in a position selected from the group consisting of: (1) serially with respect to one another along the length of the probe and (2) in parallel with one another.

13. The method of claim 1 wherein the substrate comprises a space transformer.

14. The method of claim 1 wherein the substrate is a build substrate that is removed with another substrate being bonded to one end of the plurality of probes.

15. The method claim 1 additionally comprising providing at least one deformation tool that is used in deforming the template material wherein the at least one deformation tool includes a plurality of openings which are laterally aligned with the plurality of probes and wherein the at least one deformation tool is located at at least one longitudinal position to engage the probes at at least one longitudinal height and wherein at least one of the at least one deformation tool is retained as at least one guide plate in the array when put to use.

16. The method of claim 1 wherein the at least one deformable material is selected from the group consisting of: (1) a single template material (e.g. a photoresist) that is subjected to differential processing (e.g. temperature and timing of baking, type of radiation used for exposure and quantity of exposure, and type of developer used and parameters associated with its use) at at least two longitudinal levels such that the template material has different yield strengths which in turn results in different amounts of relative deformation at that two levels when the at least one template material is subjected to the lateral displacement, and (2) at least two different template materials (e.g. two different photoresists having different base materials, different reactive chemicals, different viscosities, different coefficients of radiation absorption, or the like) which have at least two different yield strengths which in turn results in different amounts of relative deformation at the at least two levels when the at least two different template materials are subjected to the lateral displacement.

17. The method of claim 16 wherein the at least two different portions of the at least one deformable material undergo differential processing prior to locating each of the at least two different portions such that the at least two different portions will have different yield strengths at the time of exerting the lateral shearing displacement.

18. A method for forming a probe array, comprising:
(a) providing a substrate;
(b) locating at least one deformable template material directly or indirectly on the substrate or on a previously located template material, wherein the at least one template material has a bottom and a top and extends in a longitudinal direction from the bottom to the top with the bottom located closer to the substrate than the top;
(c) patterning the at least one deformable template material to form a plurality of latent openings that extend in the longitudinal direction;
(d) exerting a lateral shearing displacement by application of a lateral shearing force between at least two longitudinal levels of at least one of the at least one template material to deform the at least one of the at least one template material to create a deformed latent template that results in at least a portion of the plurality of latent openings being deformed to become deformed latent openings having orientation changes relative to latent openings prior to deformation;
(e) removing material from the latent openings to provide actualized openings; and
(f) after providing the actualized openings, depositing at least one probe material into the deformed actualized openings in the deformed template to form probes for the probe array.

19. A method for forming a probe array having a plurality of probes, comprising:
(a) providing a substrate;
(b) locating at least one deformable template material directly or indirectly on the substrate or on a previously located template material, wherein the at least one template material has a bottom and a top and extends in a longitudinal direction from the bottom to the top with the bottom located closer to the substrate than the top;
(c) patterning the at least one deformable template material to form a plurality of openings that extend in the longitudinal direction, selected from the group consisting of (1) latent openings and (2) actualized openings;
(d) exerting a lateral shearing displacement by application of a lateral shearing force between at least two longitudinal levels of at least one of the at least one template material to deform the at least one of the at least one template material to create a deformed template with openings that result in at least a portion of the plurality of openings being deformed such that orientation changes occur relative to orientation of the openings prior to deformation;
(e) actualizing any latent opening by removing material from the latent openings to provide actualized openings; and
(f) after providing actualized openings, depositing at least one probe material into the actualized openings to form a plurality of probes for the probe array.

20. The method of claim 19 wherein the order of patterning, exerting, actualizing and depositing, is selected from the group consisting of: (1) patterning followed by exerting, followed by actualizing, and then followed by depositing, (2) patterning followed by actualizing, followed by exerting, and then followed by depositing, (3) patterning followed by actualizing, followed by depositing, and then followed by exerting, (4) patterning and actualizing occurring simultaneously, followed by exerting, and then depositing, and (5) patterning and actualizing occurring simultaneously, followed by depositing, and then by exerting.
